(19) United States
(12) Patent Application Publication
(10) Pub. No.: US 2024/0224805 A1
(43) Pub. Date: Jul. 4, 2024

(54) PIEZOELECTRIC DEVICE AND APPARATUS INCLUDING THE SAME

(71) Applicant: LG Display Co., Ltd., Seoul (KR)

(72) Inventors: Sooyoun KIM, Paju-si (KR); YongWoo LEE, Paju-si (KR); HwaYoul LEE, Paju-si (KR); Uihyeon JEONG, Paju-si (KR); JounHo LEE, Paju-si (KR)

(73) Assignee: LG Display Co., Ltd., Seoul (KR)

(21) Appl. No.: 18/389,135

(22) Filed: Nov. 13, 2023

(30) Foreign Application Priority Data
Dec. 30, 2022 (KR) 10-2022-0191270

(51) Int. Cl. H10N 30/50; H10N 30/053; H10N 30/853

(52) U.S. Cl. CPC H10N 30/50; H10N 30/053; H10N 30/8536; H10N 30/8542; H10N 30/8561

(57) ABSTRACT

Discussed is a piezoelectric device that can include a piezoelectric device layer, a first electrode layer at a first surface of the piezoelectric device layer, and a second electrode layer at a second surface, differing from the first surface, of the piezoelectric device layer, wherein the piezoelectric device layer includes a first vibration portion and a second vibration portion each provided on a same plane to have different characteristics.

### CROSS-REFERENCE TO RELATED APPLICATIONS

This application claims priority to Korean Patent Application No. 10-2022-0191270 filed in the Republic of Korea on Dec. 30, 2022, the entire contents of which is hereby expressly incorporated by reference into the present application.

### BACKGROUND OF THE DISCLOSURE

### Technical Field

The present disclosure relates to a piezoelectric device and an apparatus including the same.

### Discussion of the Related Art

Piezoelectric materials are being widely used as materials of components in devices such as ultrasound vibrators, electromechanical transducers, and actuators used in the fields of ultrasound devices, video devices, sound devices, communication devices, and sensors, among other.

Pb(Zr, Ti)O₃ (PZT)-based materials have a strong piezoelectric characteristic, and thus, have been widely used as a piezoelectric material of choice in many applications. However, lead (Pb) is a material having strong toxicity and has high volatility in a sintering process, and due to this, causes serious environmental pollution that have serious environmental consequences and are costly to clean-up.

Therefore, because a PZT material having the most use among piezoelectric materials can cause such an environmental pollution problem, there is need to develop an environmentally friendly alternative to the PZT material. In this regards, a Pb-free piezoelectric material has been explored, but there is need for obtaining a strong piezoelectric characteristic in such a Pb-free piezoelectric material.

### SUMMARY OF THE DISCLOSURE

The inventors have performed various research and experiments for providing a piezoelectric device and an apparatus including the same, in which a piezoelectric characteristic and reliability can be improved without including lead (Pb). Based on the various research and experiments, the inventors have invented a piezoelectric device including a Pb-free piezoelectric material and an apparatus including the piezoelectric device.

An aspect of the present disclosure is directed to providing a piezoelectric device and an apparatus including the same, in which a piezoelectric characteristic and reliability are improved without including Pb.

Another aspect of the present disclosure is directed to providing a piezoelectric device and an apparatus including the same, in which the piezoelectric characteristic and reliability of a piezoelectric device including a Pb-free piezoelectric material are enhanced.

Another aspect of the present disclosure is directed to providing a piezoelectric device and an apparatus including the same, in which the piezoelectric characteristic and reliability of a piezoelectric device based on a multilayer structure combination of Pb-free piezoelectric materials having different characteristics are enhanced.

A piezoelectric device according to an embodiment of the present disclosure can include a piezoelectric device layer, a first electrode layer at a first surface of the piezoelectric device layer, and a second electrode layer at a second surface of the piezoelectric device layer from the first surface. The piezoelectric device layer can include a first vibration portion and a second vibration portion which are on a same plane and have different characteristics.

An apparatus according to an embodiment of the present disclosure can include a vibration member and at least one vibration apparatus configured to vibrate the vibration member, and the at least one vibration apparatus can include a piezoelectric device layer, a first electrode layer at a first surface of the piezoelectric device layer, and a second electrode layer at a second surface of the piezoelectric device layer different from the first surface. The piezoelectric device layer can include a first vibration portion and a second vibration portion which are on a same plane and have different characteristics.

According to an embodiment of the present disclosure, a piezoelectric device can include a first electrode, a piezoelectric device layer on the first electrode, and having at least one first vibration portion and at least one second vibration portion arranged adjacent to each other along at least a first direction, each of the at least one first vibration portion and the at least one second vibration portion including at least one lead (Pb)-free piezoelectric material having a relative density of 90% or more, and a piezoelectric constant of 650 pC/N or more, and a second electrode on the piezoelectric device layer.

According to an embodiment of the present disclosure, a piezoelectric device and an apparatus including the same, in which a piezoelectric characteristic and reliability are improved without including Pb, can be provided.

According to an embodiment of the present disclosure, a piezoelectric device and an apparatus including the same, in which the piezoelectric characteristic and reliability of a piezoelectric device including a Pb-free piezoelectric material are enhanced, can be provided.

According to an embodiment of the present disclosure, a piezoelectric device and an apparatus including the same, in which the piezoelectric characteristic and reliability of a piezoelectric device based on a multilayer structure combination of Pb-free piezoelectric materials having different characteristics are enhanced, can be provided.

A piezoelectric device and an apparatus including the same according to an embodiment of the present disclosure can include a Pb-free piezoelectric material, and thus, can realize an effect of preventing the toxicity of Pb and environmental pollution caused by a harmful material occurring in a sintering process, an effect of decreasing a production harmful/restrictive material, an effect of providing an environment-friendly product, and an effect of replacing a harmful material.

### BRIEF DESCRIPTION OF THE DRAWINGS

The accompanying drawings, which are included to provide a further understanding of the disclosure and are incorporated in and constitute a part of this disclosure, illustrate aspects and embodiments of the disclosure and together with the description serve to explain principles of the disclosure.

FIG. 1 illustrates a piezoelectric device according to an embodiment of the present disclosure.

FIG. 2 is a cross-sectional view taken along line I-I′ of FIG. 1 according to an embodiment of the present disclosure.

FIG. 3 illustrates another structure of a piezoelectric device of FIG. 2 according to another embodiment of the present disclosure.

FIG. 4 illustrates another structure of the piezoelectric device of FIG. 2 according to another embodiment of the present disclosure.

FIG. 5 illustrates a piezoelectric device according to another embodiment of the present disclosure.

FIG. 6 is a cross-sectional view taken along line II-II′ of FIG. 5 according to another embodiment of the present disclosure.

FIG. 7 illustrates another structure of the piezoelectric device of FIG. 6 according to another embodiment of the present disclosure.

FIG. 8 illustrates another structure of the piezoelectric device of FIG. 6 according to another embodiment of the present disclosure.

FIG. 9 illustrates a piezoelectric device according to another embodiment of the present disclosure.

FIG. 10 is a cross-sectional view taken along line III-III′ of FIG. 9 according to another embodiment of the present disclosure.

FIGS. 11 to 17 illustrate an arrangement structure of a piezoelectric device according to another embodiment of the present disclosure.

FIG. 18 illustrates an apparatus according to an embodiment of the present disclosure.

FIG. 19 is a cross-sectional view taken along line A-A′ of FIG. 18 according to an embodiment of the present disclosure.

FIG. 20 illustrates a vibration apparatus and a rear surface of a vibration member, in an apparatus according to another embodiment of the present disclosure.

FIG. 21 is a cross-sectional view taken along line B-B′ of FIG. 20 according to another embodiment of the present disclosure.

FIG. 22 illustrates a vibration apparatus and a rear surface of a vibration member, in an apparatus according to another embodiment of the present disclosure.

FIG. 23 is a cross-sectional view taken along line C-C′ of FIG. 22 according to another embodiment of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction of thereof can be exaggerated for clarity, illustration, and/or convenience.

### DETAILED DESCRIPTION OF EMBODIMENTS

Reference is now made in detail to embodiments of the present disclosure, examples of which can be illustrated in the accompanying drawings. In the following description, when a detailed description of well-known functions, structures or configurations can unnecessarily obscure aspects of the present disclosure, the detailed description thereof can have been omitted for brevity. Further, repetitive descriptions can be omitted for brevity. The progression of processing steps and/or operations described is a non-limiting example.

The sequence of steps and/or operations is not limited to that set forth herein and may be changed to occur in an order that is different from an order described herein, with the exception of steps and/or operations necessarily occurring in a particular order. In one or more examples, two operations in succession may be performed substantially concurrently, or the two operations may be performed in a reverse order or in a different order depending on a function or operation involved.

Unless stated otherwise, like reference numerals may refer to like elements throughout even when they are shown in different drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof, are clarified through the embodiments described with reference to the accompanying drawings. The present disclosure can, however, be embodied in different forms and should not be construed as limited to the embodiments set forth herein. Rather, these embodiments are examples and are provided so that this disclosure can be thorough and complete, to assist those skilled in the art to understand the inventive concepts without limiting the protected scope of the present disclosure.

Shapes (e.g., sizes, lengths, widths, heights, thicknesses, locations, radii, diameters, and areas), ratios, angles, numbers, and the like disclosed herein, including those illustrated in the drawings are merely examples, and thus, the present disclosure is not limited to the illustrated details. Any implementation described herein as an “example” is not necessarily to be construed as preferred or advantageous over other implementations. It is, however, noted that the relative dimensions of the components illustrated in the drawings are part of the present disclosure.

When the term “comprise,” “have,” “include,” “contain,” “constitute,” “made of,” “formed of,” or the like is used with respect to one or more elements, one or more other elements can be added unless a term such as “only” or the like is used. The terms used in the present disclosure are merely used in order to describe example embodiments, and are not intended to limit the scope of the present disclosure. The terms of a singular form can include plural forms unless the context clearly indicates otherwise.

The word “exemplary” is used to mean serving as an example or illustration. Aspects are example aspects. “Embodiments,” “examples,” “aspects,” and the like should not be construed as preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In one or more aspects, unless explicitly stated otherwise, an element, feature, or corresponding information (e.g., a level, range, dimension, size, or the like) is construed to include an error or tolerance range even where no explicit description of such an error or tolerance range is provided. An error or tolerance range can be caused by various factors (e.g., process factors, internal or external impact, noise, or the like). In interpreting a numerical value, the value is interpreted as including an error range unless explicitly stated otherwise.

In describing a positional relationship, when the positional relationship between two parts (e.g., layers, films, regions, components, sections, or the like) is described, for example, using “on,” “upon,” “on top of,” “over,” “under,” “above,” “below,” “beneath,” “near,” “close to,” “adjacent to,” “beside,” “next to,” “at or on a side of,” or the like, one or more parts can be located between two other parts unless a more limiting term, such as “immediate(ly),” “direct(ly),” or “close(ly),” is used. For example, when a structure is described as being positioned “on,” “upon,” “on top of,” “over,” “under,” “above,” “below,” “beneath,” “near,” “close to,” “adjacent to,” “beside,” “next to,” “at or on a side of,” or the like another structure, this description should be construed as including a case in which the structures contact each other as well as a case in which one or more additional structures are disposed or interposed therebetween. Furthermore, the terms “front,” “rear,” “back,” “left,” “right,” “top,” “bottom,” “downward,” “upward,” “upper,” “lower,” “up,” “down,” “column,” “row,” “vertical,” “horizontal,” and the like refer to an arbitrary frame of reference.

Spatially relative terms, such as “below,” “beneath,” “lower,” “on,” “above,” “upper” and the like, can be used to describe a correlation between various elements (e.g., layers, films, regions, components, sections, or the like) as shown in the drawings. The spatially relative terms are to be understood as terms including different orientations of the elements in use or in operation in addition to the orientation depicted in the drawings. For example, if the elements shown in the drawings are turned over, elements described as “below” or “beneath” other elements would be oriented “above” other elements. Thus, the term “below,” which is an example term, can include all directions of “above” and “below.” Likewise, an exemplary term “above” or “on” can include both directions of “above” and “below.”

In describing a temporal relationship, when the temporal order is described as “after,” “subsequent,” “next,” “before,” “preceding,” “prior to,” or the like a case which is not consecutive or not sequential can be included and thus one or more other events may occur therebetween, unless a more limiting term, such as “just,” “immediate(ly),” or “direct(ly)” is used.

The terms, such as “below,” “lower,” “above,” “upper” and the like, may be used herein to describe a relationship between element(s) as illustrated in the drawings. It will be understood that the terms are spatially relative and based on the orientation depicted in the drawings.

It is understood that, although the terms “first”, “second,” or the like can be used herein to describe various elements (e.g., layers, films, regions, components, sections, or the like), these elements should not be limited by these terms. These terms are used only to partition one element from another. For example, a first element could be a second element, and, similarly, a second element could be a first element, without departing from the scope of the present disclosure. Furthermore, the first element, the second element, and the like can be arbitrarily named according to the convenience of those skilled in the art without departing from the scope of the present disclosure. For clarity, the functions or structures of these elements (e.g., the first element, the second element and the like) are not limited by ordinal numbers or the names in front of the elements. Further, a first element may include one or more first elements. Similarly, a second element or the like may include one or more second elements or the like.

In describing elements of the present disclosure, the terms “first,” “second,” “A,” “B,” “(a),” “(b),” or the like can be used. These terms are intended to identify the corresponding element(s) from the other element(s), and these are not used to define the essence, basis, order, or number of the elements.

For the expression that an element (e.g., layer, film, region, component, section, or the like) is “connected,” “coupled,” “attached,” “adhered, or the like” to another element, the element can not only be directly connected, coupled, attached, adhered, or the like to another element, but also be indirectly connected, coupled, attached, adhered, or the like to another element with one or more intervening elements disposed or interposed between the elements, unless otherwise specified.

For the expression that an element (e.g., layer, film, region, component, section, or the like) “contacts,” “overlaps,” or the like with another element, the element can not only directly contact, overlap, or the like with another element, but also indirectly contact, overlap, or the like with another element with one or more intervening elements disposed or interposed between the elements, unless otherwise specified.

The phase that an element (e.g., layer, film, region, component, section, or the like) is “provided in,” “disposed in,” or the like in another element may be understood as that at least a portion of the element is provided in, disposed in, or the like in another element, or that the entirety of the element is provided in, disposed in, or the like in another element. The phase that an element (e.g., layer, film, region, component, section, or the like) “contacts,” “overlaps,” or the like with another element may be understood as that at least a portion of the element contacts, overlaps, or the like with a least a portion of another element, that the entirety of the element contacts, overlaps, or the like with a least a portion of another element, or that at least a portion of the element contacts, overlaps, or the like with the entirety of another element.

The terms such as a “line” or “direction” should not be interpreted only based on a geometrical relationship in which the respective lines or directions are parallel or perpendicular to each other, and can be meant as lines or directions having wider directivities within the range within which the components of the present disclosure can operate functionally. For example, the terms “first direction,” “second direction,” and the like, such as a direction parallel or perpendicular to “x-axis,” “y-axis,” or “z-axis,” should not be interpreted only based on a geometrical relationship in which the respective directions are parallel or perpendicular to each other, and may be meant as directions having wider directivities within the range within which the components of the present disclosure can operate functionally.

The term “at least one” should be understood as including any and all combinations of one or more of the associated listed items. For example, each of the phrases of “at least one of a first item, a second item, or a third item” and “at least one of a first item, a second item, and a third item” may represent (i) a combination of items provided by two or more of the first item, the second item, and the third item or (ii) only one of the first item, the second item, or the third item.

The expression of a first element, a second elements “and/or” a third element should be understood as one of the first, second and third elements or as any or all combinations of the first, second and third elements. By way of example, A, B and/or C can refer to only A; only B; only C; any of A, B, and C (e.g., A, B, or C); or some combination of A, B, and C (e.g., A and B; A and C; or B and C); or all of A, B, and C. Furthermore, an expression “A/B” can be understood as A and/or B. For example, an expression “A/B” can refer to only A; only B; A or B; or A and B.

In one or more aspects, the terms “between” and “among” can be used interchangeably simply for convenience unless stated otherwise. For example, an expression “between a plurality of elements” can be understood as among a plurality of elements. In another example, an expression “among a plurality of elements” can be understood as between a plurality of elements. In one or more examples, the number of elements can be two. In one or more examples, the number of elements can be more than two. Furthermore, when an element (e.g., layer, film, region, component, sections, or the like) is referred to as being “between” at least two elements, the element may be the only element between the at least two elements, or one or more intervening elements may also be present.

In one or more aspects, the phrases “each other” and “one another” can be used interchangeably simply for convenience unless stated otherwise. For example, an expression “different from each other” can be understood as being different from one another. In another example, an expression “different from one another” can be understood as being different from each other. In one or more examples, the number of elements involved in the foregoing expression can be two. In one or more examples, the number of elements involved in the foregoing expression can be more than two.

In one or more aspects, the phrases “one or more among” and “one or more of” can be used interchangeably simply for convenience unless stated otherwise.

The term “or” means “inclusive or” rather than “exclusive or.” That is, unless otherwise stated or clear from the context, the expression that “x uses a or b” means any one of natural inclusive permutations. For example, “a or b” may mean “a,” “b,” or “a and b.” For example, “a, b or c” may mean “a,” “b,” “c,” “a and b,” “b and c,” “a and c,” or “a, b and c.”

Features of various embodiments of the present disclosure can be partially or entirety coupled to or combined with each other, may be technically associated with each other, and can be variously inter-operated, linked or driven together. The embodiments of the present disclosure can be implemented or carried out independently of each other, or can be implemented or carried out together in a co-dependent or related relationship. In one or more aspects, the components of each apparatus according to various embodiments of the present disclosure are operatively coupled and configured.

Unless otherwise defined, the terms (including technical and scientific terms) used herein have the same meaning as commonly understood by one of ordinary skill in the art to which example embodiments belong. It is further understood that terms, such as those defined in commonly used dictionaries, should be interpreted as having a meaning that is, for example, consistent with their meaning in the context of the relevant art and should not be interpreted in an idealized or overly formal sense unless expressly defined otherwise herein.

The terms used herein have been selected as being general in the related technical field; however, there may be other terms depending on the development and/or change of technology, convention, preference of technicians, and so on. Therefore, the terms used herein should not be understood as limiting technical ideas, but should be understood as examples of the terms for describing example embodiments.

Further, in a specific case, a term may be arbitrarily selected by an applicant, and in this case, the detailed meaning thereof is described herein. Therefore, the terms used herein should be understood based on not only the name of the terms, but also the meaning of the terms and the content hereof.

In the following description, various example embodiments of the present disclosure are described in detail with reference to the accompanying drawings. With respect to reference numerals to elements of each of the drawings, the same elements can be illustrated in other drawings, and like reference numerals can refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings can be different from an actual scale, dimension, size, and thickness, and thus, embodiments of the present disclosure are not limited to a scale, dimension, size, and thickness illustrated in the drawings.

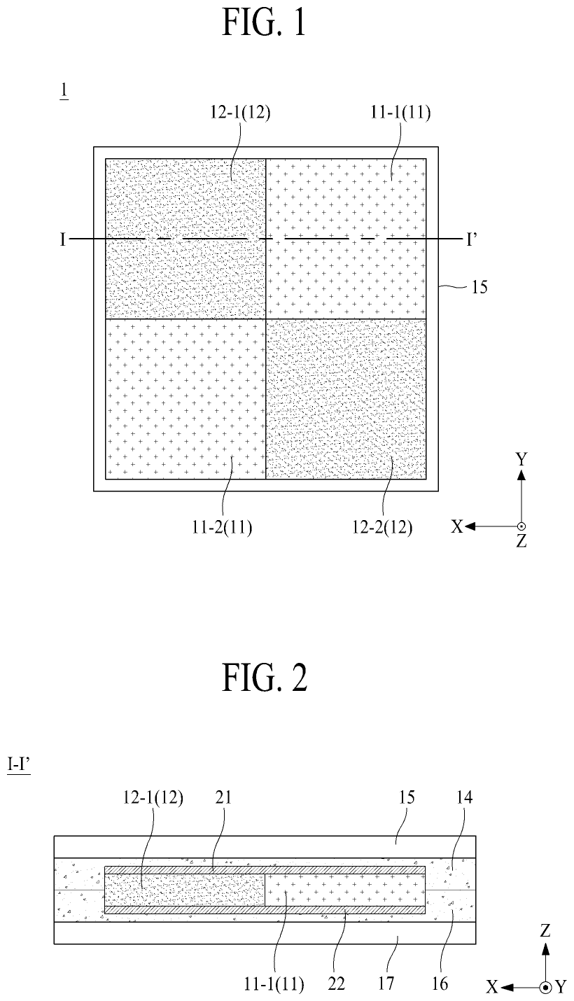

FIG. 1 illustrates a piezoelectric device 1 according to an embodiment of the present disclosure. FIG. 2 is a cross-sectional view taken along line I-I′ of FIG. 1 according to an embodiment of the present disclosure.

Referring to FIGS. 1 and 2, the piezoelectric device 1 according to an embodiment of the present disclosure can include a first vibration portion 11, a second vibration portion 12, a first electrode layer 21, and a second electrode layer 22.

The first vibration portion 11 and the second vibration portion 12 can be configured between the first electrode layer 21 and the second electrode layer 22. The first vibration portion 11 and the second vibration portion 12 can configure a single piezoelectric device layer. The first vibration portion 11 and the second vibration portion 12 can be configured on the same plane to have different characteristics. For example, the first vibration portion 11 and the second vibration portion 12 can be configured on the same plane not to overlap each other. Each of the first vibration portion 11 and the second vibration portion 12 can include a circular plate shape, a polygonal plate shape, an oval shape, or a ring shape, but embodiments of the present disclosure are not limited thereto.

Each of the first vibration portion 11 and the second vibration portion 12 can include a piezoelectric material having a piezoelectric effect (or a piezoelectric characteristic). For example, each of the first vibration portion 11 and the second vibration portion 12 can be an inorganic layer, an inorganic material layer, a piezoelectric material layer, an electroactive layer, a piezoelectric portion, an inorganic portion, an inorganic material portion, a piezoelectric material portion, or an electroactive portion, but embodiments of the present disclosure are not limited thereto.

The first vibration portion 11 and the second vibration portion 12 can include a ceramic-based material capable of implementing a relatively high vibration, or can include piezoelectric ceramic having a perovskite crystalline structure. The perovskite crystalline structure can have a piezoelectric and/or inverse piezoelectric effect and can be a plate-shaped structure having an orientation.

According to an embodiment of the present disclosure, each of the first vibration portion 11 and the second vibration portion 12 can include a lead zirconate titanate (PZT)-based piezoelectric material including Pb, zirconium (Zr), and titanium (Ti) each having a high piezoelectric characteristic, but is not limited thereto and can include a Pb-free piezoelectric material so as to prevent the toxicity of Pb and environmental pollution caused by a harmful material occurring in a sintering process. For example, the Pb-free piezoelectric material can have a problem where performance and reliability are lower than those of the PZT-based piezoelectric material. For example, the Pb-free piezoelectric material can have problem where the reliability of a piezoelectric material is affected by a low curie temperature and a piezoelectric characteristic is low due to a low piezoelectric constant. Accordingly, the inventors have invented a piezoelectric material having a characteristic which is the same as or similar to a Pb-based piezoelectric material, based on various research and experiments. This will be described below.

The first vibration portion 11 and the second vibration portion 12 according to an embodiment of the present disclosure can respectively include piezoelectric materials having different characteristics among lead (Pb)-free piezoelectric materials. For example, the first vibration portion 11 and the second vibration portion 12 can respectively include Pb-free piezoelectric materials having different characteristics.

The different characteristics of the first vibration portion 11 and the second vibration portion 12 can include one or more of a curie temperature (TC), a piezoelectric constant (d₃₃), a coercive field (EC), a relative density (%), a theoretical density or specific gravity, and a dielectric constant (¿).

The curie temperature Tc can be a temperature where a crystalline structure of a piezoelectric material is changed to a cubic structure, can be a threshold temperature where a piezoelectric characteristic is reduced, and can be a factor which affects the reliability of a piezoelectric material. For example, one of the first vibration portion 11 and the second vibration portion 12 can include a piezoelectric material where the curie temperature Tc is 170° C. or more. For example, the piezoelectric material where the curie temperature Tc is 170° C. or more can implement or realize the enhancement of reliability of the piezoelectric device 1.

The piezoelectric constant d₃₃ can represent the amount of electric charges which are generated in a pressure direction applied to a piezoelectric material and can be a factor which affects a driving characteristic of a piezoelectric material. For example, one of the first vibration portion 11 and the second vibration portion 12 can include a piezoelectric material where the piezoelectric constant d₃₃ is 700 pC/N or more or is 650 pC/N to 800 pC/N. For example, the piezoelectric material where the piezoelectric constant d₃₃ is 700 pC/N or more or is 650 pC/N to 800 pC/N can implement or realize the enhancement of driving characteristic of the piezoelectric device 1.

The coercive field Ec can represent a magnitude of an electric field where polarization is 0 and can be a factor representing a large strain characteristic. For example, one of the first vibration portion 11 and the second vibration portion 12 can include a piezoelectric material where the coercive field Ec is 10 kV/cm or more. For example, the piezoelectric material where the coercive field Ec is 10 kV/cm or more can implement or realize a large strain characteristic of the piezoelectric device 1.

The relative density (%) can be a percentage where a measurement density based on sintering of a piezoelectric material is divided by a theoretical density and can be a factor representing a sintering characteristic. For example, one of the first vibration portion 11 and the second vibration portion 12 can include a piezoelectric material where the relative density (%) is 90% or more or is 95% or more.

The first vibration portion 11 and the second vibration portion 12 according to an embodiment of the present disclosure can include one or more of different characteristics.

One of the first vibration portion 11 and the second vibration portion 12 can include one or more of a relative density of 90% or more and a curie temperature of 170° C. or more. For example, one of the first vibration portion 11 and the second vibration portion 12 can include a piezoelectric material including a relative density of 90% or more and a curie temperature of 170° C. or more. Also, the piezoelectric material including a relative density of 90% or more and a curie temperature of 170° C. or more can include a piezoelectric constant of 650 pC/N to 800 pC/N. For example, one of the first vibration portion 11 and the second vibration portion 12 can include a piezoelectric material including a relative density of 90% or more, a curie temperature of 170° C. or more, and a piezoelectric constant of 650 pC/N to 800 pC/N. For example, one of the first vibration portion 11 and the second vibration portion 12 can include a piezoelectric material including one or more of a relative density of 90% or more, a curie temperature of 170° C. or more, and a piezoelectric constant of 650 pC/N to 800 pC/N, and the other of the first vibration portion 11 and the second vibration portion 12 can include a piezoelectric material having a different characteristic.

One of the first vibration portion 11 and the second vibration portion 12 can include one or more of a relative density of 95% or more and a piezoelectric constant of 700 pC/N or more. For example, one of the first vibration portion 11 and the second vibration portion 12 can include a piezoelectric material including a relative density of 95% or more and a piezoelectric constant of 700 pC/N or more. For example, one of the first vibration portion 11 and the second vibration portion 12 can include a piezoelectric material including one or more of a relative density of 95% or more and a piezoelectric constant of 700 pC/N or more, and the other of the first vibration portion 11 and the second vibration portion 12 can include a piezoelectric material having a different characteristic.

One of the first vibration portion 11 and the second vibration portion 12 can include one or more of a coercive field of 10 kV/cm or more and a piezoelectric constant of 200 pC/N to 500 pC/N. For example, one of the first vibration portion 11 and the second vibration portion 12 can include a piezoelectric material including a coercive field of 10 kV/cm or more and a piezoelectric constant of 200 pC/N to 500 pC/N. For example, one of the first vibration portion 11 and the second vibration portion 12 can include a piezoelectric material including one or more of a coercive field of 10 kV/cm or more and a piezoelectric constant of 200 pC/N to 500 pC/N, and the other of the first vibration portion 11 and the second vibration portion 12 can include a piezoelectric material having a different characteristic.

The first vibration portion 11 and the second vibration portion 12 can include different materials of a potassium sodium niobite (KNN)-based piezoelectric material including potassium (K), sodium (Na), and niobium (Nb), a barium titanate (BT)-based piezoelectric material, and a bismuth (Bi)-based piezoelectric material. For example, the KNN-based piezoelectric material can include (K,Na)NbO₃, but embodiments of the present disclosure are not limited thereto. For example, the BT-based piezoelectric material can include Ba(Ti,Zr)O₃ or (Ba,Ca)TiO₃—Ba(Ti,Zr)O₃, but embodiments of the present disclosure are not limited thereto. For example, the Bi-based piezoelectric material can include at least one of (Na,Bi)TiO₃—BaTiO₃, BiFeO₃, Bi_{0.5}Na_{0.5}TiO₃(BNT), Bi(Na,K)TiO₃-BT-KNN, and (Bi, Na)TiO₃, but embodiments of the present disclosure are not limited thereto. Also, templated grain growth (TGG) can be applied to the KNN-based piezoelectric material, or can be not applied thereto. For example, one of the first vibration portion 11 and the second vibration portion 12 can include a KNN-based piezoelectric material to which TGG is applied, and the other of the first vibration portion 11 and the second vibration portion 12 can include a KNN-based piezoelectric material to which TGG is not applied.

Each of the first vibration portion 11 and the second vibration portion 12 according to an embodiment of the present disclosure can include one or more material portions. For example, the first vibration portion 11 can include one or more first material portions 11-1 and 11-2. Also, the second vibration portion 12 can include one or more second material portions 12-1 and 12-2. The one or more first material portions 11-1 and 11-2 and the one or more second material portions 12-1 and 12-2 can have different characteristics. For example, the one or more first material portions 11-1 and 11-2 and the one or more second material portions 12-1 and 12-2 can include piezoelectric materials having different characteristics. For example, the one or more first material portions 11-1 and 11-2 and the one or more second material portions 12-1 and 12-2 can include Pb-free piezoelectric materials. For example, the one or more first material portions 11-1 and 11-2 and the one or more second material portions 12-1 and 12-2 can include Pb-free piezoelectric materials having different characteristics.

According to an embodiment of the present disclosure, each of the one or more first material portions 11-1 and 11-2 can include a piezoelectric material including one or more of a higher curie temperature and a less piezoelectric constant than those of each of the one or more second material portions 12-1 and 12-2.

Each of the one or more first material portions 11-1 and 11-2 can include one or more of a relative density of 90% or more and a curie temperature of 170° C. or more. For example, each of the one or more first material portions 11-1 and 11-2 can include a piezoelectric material including a relative density of 90% or more and a curie temperature of 170° C. or more. For example, each of the one or more first material portions 11-1 and 11-2 can include a KNN-based piezoelectric material including K, Na, and Nb. The one or more first material portions 11-1 and 11-2 can be configured or implemented to enhance or improve the reliability of the piezoelectric device 1.

In various embodiments of the present disclosure, the piezoelectric device 1 can include a piezoelectric layer (11 and 12) including one or more vibration portions. The one or more vibration portions can include at least one first vibration portion 11 and at least one second vibration portion 12. Each of the at least one first vibration portion 11 and the at least one second vibration portion 12 can include at least one lead-free piezoelectric material having a relative density of 90% or more, and a piezoelectric constant of 650 pC/N or more. In this context, the at least one lead-free piezoelectric material can include a first lead-free piezoelectric material having the relative density of 90% or more and a curie temperature of 170° C. or more, or a second lead-free piezoelectric material having the relative density of 95% or more and the piezoelectric constant of 700 pC/N or more.

For example, the one or more first material portions 11-1 and 11-2 can be represented by the following Chemical Formula 1.

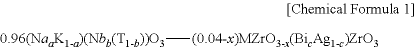

In Chemical Formula 1, T can denote antimony (Sb) or tantalum (Ta), M can denote strontium (Sr), barium (Ba), or calcium (Ca), 0.40≤a≤0.60, 0.90≤b≤0.98, 0.30≤c≤0.70, and 0.00≤x≤0.04.

In a case where TGG is applied, NaNbO₃ and FezO₃ can be further included in Chemical Formula 1. For example, NaNbO₃ can be added to Chemical Formula 1 by 5 mol % or less and Fe₂O₃ can be added to Chemical Formula 1 by 5 mol % or less, but embodiments of the present disclosure are not limited thereto. In a case where TGG is not applied, FezO₃ can be further included in Chemical Formula 1. For example, Fe₂O₃ can be added to Chemical Formula 1 by 5 mol % or less, but embodiments of the present disclosure are not limited thereto.

According to another embodiment, the one or more first material portions 11-1 and 11-2 can be represented by the following Chemical Formula 2.

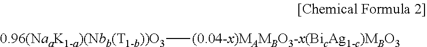

In Chemical Formula 2, T can denote antimony (Sb), tantalum (Ta), or vanadium (V), M_{A} can denote Sr, Ba, or Ca, M_{B} can denote zirconium (Zr), hafnium (Hf), titanium (Ti), or tin (Sn), E can denote the second material, 0.40≤a≤0.60, 0.90≤b≤1.00, 0.30≤c≤0.70, and 0.00≤x≤0.04.

In a case where TGG is applied, NaNbO₃ and FezO₃ can be further included in Chemical Formula 2. For example, NaNbO₃ can be added to Chemical Formula 2 by 5 mol % or less and Fe₂O₃ can be added to Chemical Formula 2 by 5 mol % or less, but embodiments of the present disclosure are not limited thereto. In a case where TGG is not applied, FezO₃ can be further included in Chemical Formula 2. For example, Fe₂O₃ can be added to Chemical Formula 2 by 5 mol % or less, but embodiments of the present disclosure are not limited thereto.

Each of the one or more second material portions 12-1 and 12-2 can have one or more of a relative density of 95% or more and a piezoelectric constant of 700 pC/N or more. For example, each of the one or more second material portions 12-1 and 12-2 can include a piezoelectric material which has a relative density of 95% or more and a piezoelectric constant of 700 pC/N or more. For example, each of the one or more second material portions 12-1 and 12-2 can include a BT-piezoelectric material. The BT-based piezoelectric material can include (Ba,Ca)TiO₃—Ba(Ti,Zr)O₃, but embodiments of the present disclosure are not limited thereto. For example, the Bi-based piezoelectric material can include at least one of (Na,Bi)TiO₃—BaTiO₃, BiFeO₃, Bi_{0.5}Na_{0.5}TiO₃(BNT), Bi(Na,K)TiO₃-BT-KNN, and (Bi, Na)TiO₃, but embodiments of the present disclosure are not limited thereto. The one or more second material portions 12-1 and 12-2 can be configured or implemented to enhance or improve a driving characteristic of the piezoelectric device 1.

According to an embodiment of the present disclosure, the reliability of the one or more second material portions 12-1 and 12-2 can be complemented based on a high relative density and/or a high curie temperature of the one or more first material portions 11-1 and 11-2, and a low piezoelectric characteristic of the one or more first material portions 11-1 and 11-2 can be complemented by the one or more second material portions 12-1 and 12-2 having a high relative density and/or a high piezoelectric constant.

According to an embodiment of the present disclosure, the one or more second material portions 12-1 and 12-2 can be provided adjacent to the one or more first material portions 11-1 and 11-2. For example, a barium titanate (BT)-based piezoelectric material can be provided adjacent to a potassium sodium niobite (KNN)-based piezoelectric material. For example, the one or more first material portions 11-1 and 11-2 can be configured adjacent to the one or more second material portions 12-1 and 12-2 to have an equal area. The KNN-based piezoelectric material can be configured adjacent to the BT-based piezoelectric material to have an equal area. Because the KNN-based piezoelectric material is configured adjacent to the BT-based piezoelectric material to have an equal area, a degradation in the piezoelectric device 1 caused by a low curie temperature of the BT-based piezoelectric material can be prevented or reduced, and thus, the reliability of the piezoelectric device 1 can be enhanced, thereby enhancing a vibration characteristic of the piezoelectric device 1 based on a high piezoelectric constant of the BT-based piezoelectric material. The one or more first material portions 11-1 and 11-2 and the one or more second material portions 12-1 and 12-2 according to an embodiment of the present disclosure can have different thicknesses or the same thickness. For example, the one or more first material portions 11-1 and 11-2 and the one or more second material portions 12-1 and 12-2 can have substantially the same height within an error range of a manufacturing process. Also, the one or more first material portions 11-1 and 11-2 and the one or more second material portions 12-1 and 12-2 can have different sizes or the same size. For example, the one or more first material portions 11-1 and 11-2 and the one or more second material portions 12-1 and 12-2 can have substantially the same size within an error range of a manufacturing process. Also, the number of one or more first material portions 11-1 and 11-2 can be equal to or different from the number of one or more second material portions 12-1 and 12-2. For example, the number of one or more first material portions 11-1 and 11-2 can be equal to the number of one or more second material portions 12-1 and 12-2. For example, the one or more first material portions 11-1 and 11-2 can include a first-1 material portion 11-1 and a first-2 material portion 11-2. For example, the one or more second material portions 12-1 and 12-2 can include a second-1 material portion 12-1 and a second-2 material portion 12-2.

Each of the one or more first material portions 11-1 and 11-2 and the one or more second material portions 12-1 and 12-2 can include a tetragonal shape which has a first length parallel to a first direction X and a second length parallel to a second direction Y intersecting with the first direction X. For example, each of the one or more first material portions 11-1 and 11-2 and the one or more second material portions 12-1 and 12-2 can include a square shape where the first length is equal to the second length, but embodiments of the present disclosure are not limited thereto.

The one or more first material portions 11-1 and 11-2 and the one or more second material portions 12-1 and 12-2 can be disposed adjacent to each other in the first direction X or the second direction Y in the same plane. For example, the first-1 material portion 11-1 and the second-1 material portion 12-1 can be arranged adjacent to each other in the first direction X. The first-1 material portion 11-1 and the second-1 material portion 12-1 can be arranged in parallel in the second direction Y. Also, the first-1 material portion 11-1 can be disposed at a right periphery of the second-1 material portion 12-1, and the second-1 material portion 12-1 can be disposed at a left periphery of the first-1 material portion 11-1. Also, the second-2 material portion 12-2 and the first-2 material portion 11-2 can be arranged adjacent to each other in the first direction X. The second-2 material portion 12-2 and the first-2 material portion 11-2 can be arranged in parallel in the second direction Y. Also, the second-2 material portion 12-2 can be disposed at a right periphery of the first-2 material portion 11-2, and the first-2 material portion 11-2 can be disposed at a left periphery of the second-2 material portion 12-2. Also, the first-1 material portion 11-1 and the second-2 material portion 12-2 can be arranged adjacent to each other in the second direction Y. The first-1 material portion 11-1 and the second-2 material portion 12-2 can be arranged in parallel in the first direction X. Also, the first-1 material portion 11-1 can be disposed at an upper periphery of the second-2 material portion 12-2, and the second-2 material portion 12-2 can be disposed at a lower periphery of the first-1 material portion 11-1. Also, the second-1 material portion 12-1 and the first-2 material portion 11-2 can be arranged adjacent to each other in the second direction Y. The second-1 material portion 12-1 and the first-2 material portion 11-2 can be arranged in parallel in the first direction X. Also, the second-1 material portion 12-1 can be disposed at an upper periphery of the first-2 material portion 11-2, and the first-2 material portion 11-2 can be disposed at a lower periphery of the second-1 material portion 12-1.

In embodiments of the present disclosure, locations of the first vibration portion 11, which includes the first material portions 11-1 and 11-2, and the second vibration portion 12, which includes the second material portions 12-1 and 12-2 in the piezoelectric device 1 can also be described as portions of quadrants. For example, with reference to FIG. 1, the piezoelectric device 1 includes the first-1 material portion 11-1 in an upper left quadrant (e.g., quadrant 1) and the first-2 material portion 11-2 in a lower left quadrant (e.g., quadrant 3), which are opposite quadrants. Also, the piezoelectric device 1 includes the first-2 material portion 12-1 in an upper right quadrant (e.g., quadrant 4) and the second-2 material portion 12-2 in a lower right quadrant (e.g., quadrant 2), which are opposite quadrants. When arranged in the quadrants, at least one first vibration portion 11 (such as the first-1 material portion 11-1)) and at least one second vibration portion 12 (such as the second 1 material portion (12-1)) are arranged adjacent to each other along a first direction X (see FIG. 2).

According to an embodiment of the present disclosure, the reliability of the one or more second material portions 12-1 and 12-2 can be complemented based on a high relative density and/or a high curie temperature of the one or more first material portions 11-1 and 11-2, and a low piezoelectric characteristic of the one or more first material portions 11-1 and 11-2 can be complemented by the one or more second material portions 12-1 and 12-2 having a high relative density and/or a high piezoelectric constant.

According to an embodiment of the present disclosure, the one or more second material portions 12-1 and 12-2 can be provided adjacent to the one or more first material portions 11-1 and 11-2. For example, the KNN-based piezoelectric material can be configured adjacent to the BT-based piezoelectric material. Because the KNN-based piezoelectric material is configured adjacent to the BT-based piezoelectric material, a degradation in the piezoelectric device 1 caused by a low curie temperature of the BT-based piezoelectric material can be prevented, and thus, the reliability of the piezoelectric device 1 can be enhanced, thereby enhancing a vibration characteristic of the piezoelectric device 1 based on a high piezoelectric constant of the BT-based piezoelectric material.

The first electrode layer 21 and the second electrode layer 22 can be configured to face each other with the first vibration portion 11 and the second vibration portion 12 therebetween. For example, the first electrode layer 21 and the second electrode layer 22 can be configured to face each other with the one or more first material portions 11-1 and 11-2 of the first vibration portion 11 and the one or more second material portions 12-1 and 12-2 of the second vibration portion 12 therebetween.

The first electrode layer 21 can be disposed in common at a first surface (or an upper surface) of each of the first electrode layer 21 and the second electrode layer 22. The first electrode layer 21 can have a size which is less than or equal to a total size of the first electrode layer 21 and the second electrode layer 22. The second electrode layer 22 can be disposed in common at a second surface (or a lower surface) of each of the first electrode layer 21 and the second electrode layer 22. The second electrode layer 22 can have a size which is less than or equal to the total size of the first electrode layer 21 and the second electrode layer 22. The first electrode layer 21 and the second electrode layer 22 can have the same size or different sizes. For example, the first electrode layer 21 and the second electrode layer 22 can have substantially the same size within an error range of a manufacturing process.

According to an embodiment of the present disclosure, in order to prevent an electrical connection (or short circuit) between the first electrode layer 21 and the second electrode layer 22, the first electrode layer 21 and the second electrode layer 22 can be respectively formed at the other portions, except edge portions, of the first vibration portion 11 and the second vibration portion 12. For example, the first electrode layer 21 can be formed at the other whole portion, except an edge portion, of a first surface (or an upper surface) of each of the first vibration portion 11 and the second vibration portion 12. For example, the first electrode layer 21 can be formed at the other whole portion except an upper and right edge portion of the first-1 material portion 11-1, an upper and left edge portion of the second-1 material portion 12-1, a lower and right edge portion of the second-2 material portion 12-2, and a lower and left edge portion of the first-2 material portion 11-1. For example, the second electrode layer 22 can be formed at the other whole portion, except an edge portion, of a second surface (or a lower surface) of each of the first vibration portion 11 and the second vibration portion 12. For example, the second electrode layer 22 can be formed at the other whole portion except the upper and right edge portion of the first-1 material portion 11-1, the upper and left edge portion of the second-1 material portion 12-1, the lower and right edge portion of the second-2 material portion 12-2, and the lower and left edge portion of the first-2 material portion 11-1.

According to an embodiment of the present disclosure, each of the first electrode layer 21 and the second electrode layer 22 can include a transparent conductive material, a semitransparent conductive material, or an opaque conductive material. For example, the transparent or semitransparent conductive material can include indium tin oxide (ITO) or indium zinc oxide (IZO), but embodiments of the present disclosure are not limited thereto. The opaque conductive material can include gold (Au), silver (Ag), platinum (Pt), palladium (Pd), molybdenum (Mo), magnesium (Mg), or glass frit-containing Ag, or an alloy thereof, but embodiments of the present disclosure are not limited thereto. For example, each of the first electrode layer 21 and the second electrode layer 22 can include Ag having low resistivity, so as to enhance an electrical characteristic and/or a vibration characteristic of the piezoelectric device 1. For example, carbon can be a carbon material including graphite, carbon black, ketjen black, and carbon nanotube.

Each of the one or more first material portions 11-1 and 11-2 and the one or more second material portions 12-1 and 12-2 can be individually formed through a tape casting process. The one or more first material portions 11-1 and 11-2 and the one or more second material portions 12-1 and 12-2 can be arranged or configured as a matrix type on the same plane to have an equal area.

The piezoelectric device 1 according to the present disclosure can be configured so that a total thickness of the first electrode layer 21 and the second electrode layer 22 provided with the first vibration portion 11 and the second vibration portion 12 therebetween is set to tens μm to several mm. For example, a total thickness of the piezoelectric device 1 can be configured to 100 μm to 200 μm, based on design-based details of the piezoelectric device 1, but embodiments of the present disclosure are not limited thereto.

The piezoelectric device 1 according to an embodiment of the present disclosure can further include a first cover member 15 and a second cover member 17.

The first cover member 15 can be disposed on a first surface (or an upper surface) of the first vibration portion 11 and the second vibration portion 12. For example, the first cover member 15 can be configured to cover the first electrode layer 21. Accordingly, the first cover member 15 can protect the first electrode layer 21.

The second cover member 17 can be disposed on a second surface (or a lower surface) of the first vibration portion 11 and the second vibration portion 12. For example, the second cover member 17 can be configured to cover the second electrode layer 22. Accordingly, the second cover member 17 can protect the second electrode layer 22.

Each of the first cover member 15 and the second cover member 17 according to an embodiment of the present disclosure can include one or more materials of plastic, fiber, and wood, but embodiments of the present disclosure are not limited thereto. For example, the first cover member 15 and the second cover member 17 can include the same material or different materials. For example, the first cover member 15 and the second cover member 17 can be a polyimide film or a polyethylene terephthalate film, but embodiments of the present disclosure are not limited thereto.

The first cover member 15 according to an embodiment of the present disclosure can be connected or coupled to the first electrode layer 21 by using a first adhesive layer 14. For example, the first cover member 15 can be connected or coupled to the first electrode layer 21 through a film laminating process using the first adhesive layer 14.

The second cover member 17 according to an embodiment of the present disclosure can be connected or coupled to the second electrode layer 22 by a second adhesive layer 16. For example, the second cover member 17 can be connected or coupled to the second electrode layer 22 through a film laminating process by the second adhesive layer 16.

The first adhesive layer 14 can be disposed between the first electrode layer 21 and the first cover member 15. The second adhesive layer 16 can be disposed between the second electrode layer 22 and the second cover member 17. For example, the first adhesive layer 14 and the second adhesive layer 16 can be provided between the first cover member 15 and the second cover member 17 to fully surround the first vibration portion 11, the second vibration portion 12, the first electrode layer 21, and the second electrode layer 22. For example, the first vibration portion 11, the second vibration portion 12, the first electrode layer 21, and the second electrode layer 22 can be buried or embedded between the first adhesive layer 14 and the second adhesive layer 16.

Each of the first adhesive layer 14 and the second adhesive layer 16 according to an embodiment of the present disclosure can include an electrical insulation material which has adhesive properties and is capable of compression and/or decompression. For example, each of the first adhesive layer 14 and the second adhesive layer 16 can include epoxy resin, acrylic resin, silicone resin, and urethane resin, but embodiments of the present disclosure are not limited thereto. Any one of the first cover member 15 and the second cover member 17 can be attached or coupled (or connected) to the vibration member (or a vibration plate or a vibration object) via an adhesive member.

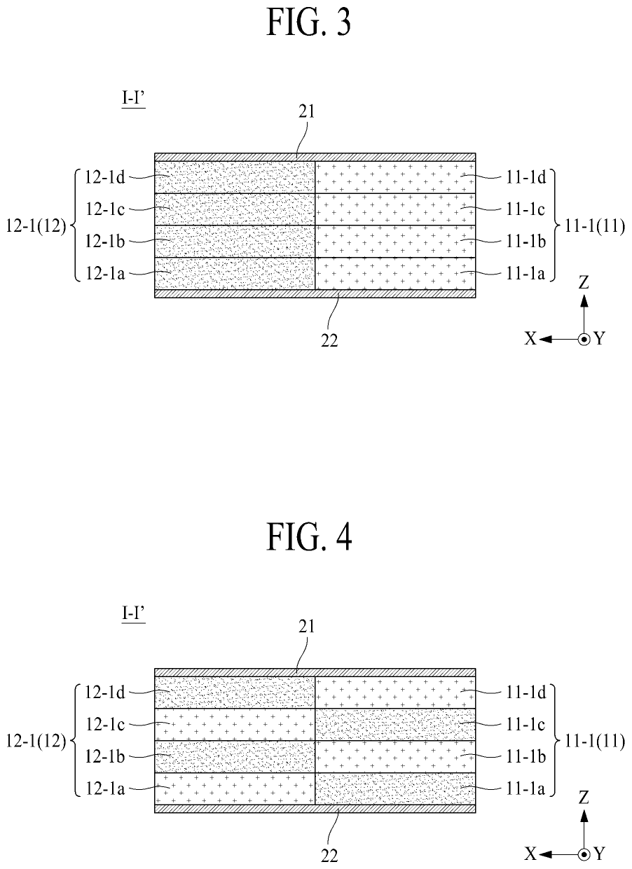

FIGS. 3 and 4 illustrate another structure of the piezoelectric device of FIG. 2 according to another embodiment of the present disclosure. FIGS. 3 and 4 illustrate another structure of the piezoelectric device 1 described above with reference to FIGS. 1 and 2. In the following description, therefore, the same elements other than a structure of a piezoelectric device and relevant elements are referred to by like reference numerals, and repeated descriptions thereof are omitted or will be only briefly given.

Referring to FIGS. 3 and 4, each of a first vibration portion 11 and a second vibration portion 12 of a piezoelectric device 1 according to another embodiment of the present disclosure can be configured with a plurality of material layers.

Each of the first vibration portion 11 and the second vibration portion 12 can include a plurality of material layers which overlap one another in a thickness direction Z. For example, a first-1 material portion 11-1 of the first vibration portion 11 can include a plurality of material layers 11-1a to 11-1d. Also, a second-1 material portion 12-1 of the second vibration portion 12 can include a plurality of material layers 12-1a to 12-1d. For example, the first-1 material portion 11-1 can include a first material layer 11-1a, a second material layer 11-1b, a third material layer 11-1c, and a fourth material layer 11-1d, but embodiments of the present disclosure are not limited thereto. Also, the second-1 material portion 12-1 can include a first material layer 12-1a, a second material layer 12-1b, a third material layer 12-1c, and a fourth material layer 12-1d, but embodiments of the present disclosure are not limited thereto.

The plurality of material layers 11-1a to 11-1d included in the first-1 material portion 11-1 can respectively include piezoelectric materials having the same characteristic or different characteristics. Also, the plurality of material layers 12-1a to 12-1d included in the second-1 material portion 12-1 can respectively include piezoelectric materials having the same characteristic or different characteristics.

According to an embodiment of the present disclosure, as illustrated in FIG. 3, the plurality of material layers 11-1a to 11-1d included in the first-1 material portion 11-1 can include the same piezoelectric material. Also, the plurality of material layers 12-1a to 12-1d included in the second-1 material portion 12-1 can include the same piezoelectric material.

Each of the plurality of material layers 11-1a to 11-1d included in the first-1 material portion 11-1 can have a relative density of 90% or more and a curie temperature of 170° C. or more. For example, each of the plurality of material layers 11-1a to 11-1d can include a piezoelectric material which has a relative density of 90% or more and a curie temperature of 170° C. or more. For example, each of the plurality of material layers 11-1a to 11-1d can include a KNN-based piezoelectric material including potassium (K), sodium (Na), and niobium (Nb). For example, the KNN-based piezoelectric material can include (K,Na)NbO₃, but embodiments of the present disclosure are not limited thereto. The plurality of material layers 11-1a to 11-1d can be configured or implemented to enhance or improve the reliability of the piezoelectric device 1.

Each of the plurality of material layers 12-1a to 12-1d included in the second-1 material portion 12-1 can have a relative density of 95% or more and a piezoelectric constant of 700 pC/N or more. For example, each of the plurality of material layers 12-1a to 12-1d can include a piezoelectric material which has a relative density of 95% or more and a piezoelectric constant of 700 pC/N or more. For example, each of the plurality of material layers 12-1a to 12-1d can include a BT-based piezoelectric material or a bismuth (Bi)-based piezoelectric material. For example, the BT-based piezoelectric material can include (Ba,Ca)TiO₃—Ba(Ti,Zr)O₃, but embodiments of the present disclosure are not limited thereto. For example, the Bi-based piezoelectric material can include at least one of (Na,Bi)TiO₃—BaTiO₃, BiFeO₃, Bi_{0.5}Na_{0.5}TiO₃(BNT), Bi(Na,K)TiO₃-BT-KNN, and (Bi,Na)TiO₃, but embodiments of the present disclosure are not limited thereto. The plurality of material layers 12-1a to 12-1d can be configured or implemented to enhance or improve the reliability of the piezoelectric device 1.

According to another embodiment of the present disclosure, the reliability of the plurality of material layers 12-1a to 12-1d included in the second-1 material portion 12-1 can be complemented by a high relative density and/or a high curie temperature of the plurality of material layers 11-1a to 11-1d included in the first-1 material portion 11-1, and a low piezoelectric characteristic of the plurality of material layers 11-1a to 11-1d included in the first-1 material portion 11-1 can be complemented by the plurality of material layers 12-1a to 12-1d included in the second-1 material portion 12-1 having a high relative density and/or a high piezoelectric constant.

According to another embodiment of the present disclosure, the plurality of material layers 11-1a to 11-1d included in the first-1 material portion 11-1 can be configured adjacent to the plurality of material layers 12-1a to 12-1d included in the second-1 material portion 12-1. For example, the KNN-based piezoelectric material can be configured adjacent to the BT-based piezoelectric material. Because the KNN-based piezoelectric material is configured adjacent to the BT-based piezoelectric material, a degradation in the piezoelectric device 1 caused by a low curie temperature of the BT-based piezoelectric material can be prevented, and thus, the reliability of the piezoelectric device 1 can be enhanced, thereby enhancing a vibration characteristic of the piezoelectric device 1 based on a high piezoelectric constant of the BT-based piezoelectric material.

Each of the plurality of material layers 11-1a to 11-1d included in the first-1 material portion 11-1 and the plurality of material layers 12-1a to 12-1d included in the second-1 material portion 12-1 can be individually formed through a tape casting process.

The plurality of material layers 11-1a to 11-1d included in the first-1 material portion 11-1 can be provided or implemented to be sequentially stacked. For example, the first material layer 11-1a of the first-1 material portion 11-1 can be disposed at a first surface (or an upper surface) of the second electrode layer 22. Also, the second material layer 11-1b of the first-1 material portion 11-1 can be disposed at a first surface (or an upper surface) of the first material layer 11-1a. Also, the third material layer 11-1c of the first-1 material portion 11-1 can be disposed at a first surface (or an upper surface) of the second material layer 11-1b. Also, the fourth material layer 11-1d of the first-1 material portion 11-1 can be disposed at a first surface (or an upper surface) of the third material layer 11-1c. Also, the first electrode layer 21 can be disposed at a first surface (or an upper surface) of the fourth material layer 11-1d.

The plurality of material layers 12-1a to 12-1d included in the second-1 material portion 12-1 can be provided or implemented to be sequentially stacked. For example, the second material layer 12-1a of the second-1 material portion 12-1 can be disposed at a first surface (or an upper surface) of the second electrode layer 22. Also, the second material layer 12-1b of the second-1 material portion 12-1 can be disposed at a first surface (or an upper surface) of the first material layer 12-1a. Also, the third material layer 12-1c of the second-1 material portion 12-1 can be disposed at a first surface (or an upper surface) of the second material layer 12-1b. Also, the fourth material layer 12-1d of the second-1 material portion 12-1 can be disposed at a first surface (or an upper surface) of the third material layer 12-1c. Also, the first electrode layer 21 can be disposed at a first surface (or an upper surface) of the fourth material layer 12-1d.

According to another embodiment of the present disclosure, as illustrated in FIG. 4, the plurality of material layers 11-1a to 11-1d included in the first-1 material portion 11-1 can respectively include different piezoelectric materials. For example, some of the plurality of material layers 11-1a to 11-1d can include the same piezoelectric material, and the other of the plurality of material layers 11-1a to 11-1d can include different piezoelectric materials. Also, the plurality of material layers 12-1a to 12-1d included in the second-1 material portion 12-1 can respectively include different piezoelectric materials. For example, some of the plurality of material layers 12-1a to 12-1d can include the same piezoelectric material, and the other of the plurality of material layers 12-1a to 12-1d can include different piezoelectric materials.

Some of the plurality of material layers 11-1a to 11-1d included in the first-1 material portion 11-1 can have one or more of a relative density of 90% or more and a curie temperature of 170° C. or more. For example, some of the plurality of material layers 11-1a to 11-1d can include a piezoelectric material which has a relative density of 90% or more and a curie temperature of 170° C. or more. For example, some of the plurality of material layers 11-1a to 11-1d can include a KNN-based piezoelectric material including K, Na, and Nb. For example, the KNN-based piezoelectric material can include (K,Na)NbO₃, but embodiments of the present disclosure are not limited thereto. Some of the plurality of material layers 11-1a to 11-1d can be configured or implemented to enhance or improve the reliability of the piezoelectric device 1. For example, the second material layer 11-1b and the fourth material layer 11-1d of the plurality of material layers 11-1a to 11-1d included in the first-1 material portion 11-1 can include a KNN-based piezoelectric material, but embodiments of the present disclosure are not limited thereto. For example, the second material layer 11-1b and the fourth material layer 11-1d can be represented by Chemical Formula 1 or Chemical Formula 2, but embodiments of the present disclosure are not limited thereto.

The other of the plurality of material layers 11-1a to 11-1d included in the first-1 material portion 11-1 can have a relative density of 95% or more and a piezoelectric constant of 700 pC/N or more. For example, each of the plurality of material layers 11-1a to 11-1d can include a piezoelectric material which has a relative density of 95% or more and a piezoelectric constant of 700 pC/N or more. For example, the other of the plurality of material layers 11-1a to 11-1d can include a BT-based piezoelectric material. For example, the BT-based piezoelectric material can include (Ba,Ca)TiO₃—Ba(Ti,Zr)O₃, but embodiments of the present disclosure are not limited thereto. The other of the plurality of material layers 11-1a to 11-1d can be configured or implemented to enhance or improve the reliability of the piezoelectric device 1. For example, the first material layer 11-1a and the third material layer 11-1c of the plurality of material layers 11-1a to 11-1d included in the first-1 material portion 11-1 can include a BT-based piezoelectric material, but embodiments of the present disclosure are not limited thereto.

Some of the plurality of material layers 12-1a to 12-1d included in the second-1 material portion 12-1 can have one or more of a relative density of 90% or more and a curie temperature of 170° C. or more. For example, some of the plurality of material layers 12-1a to 12-1d can include a piezoelectric material which has a relative density of 90% or more and a curie temperature of 170° C. or more. For example, some of the plurality of material layers 12-1a to 12-1d can include a KNN-based piezoelectric material including K, Na, and Nb. For example, the KNN-based piezoelectric material can include (K,Na)NbO₃, but embodiments of the present disclosure are not limited thereto. Some of the plurality of material layers 12-1a to 12-1d can be configured or implemented to enhance or improve the reliability of the piezoelectric device 1. For example, the first material layer 12-1a and the third material layer 12-1c of the plurality of material layers 12-1a to 12-1d included in the second-1 material portion 12-1 can include a KNN-based piezoelectric material, but embodiments of the present disclosure are not limited thereto. For example, the first material layer 12-1a and the third material layer 12-1c can be represented by Chemical Formula 1 or Chemical Formula 2, but embodiments of the present disclosure are not limited thereto.

The other of the plurality of material layers 12-1a to 12-1d included in the second-1 material portion 12-1 can have a relative density of 95% or more and a piezoelectric constant of 700 pC/N or more. For example, each of the plurality of material layers 12-1a to 12-1d can include a piezoelectric material which has a relative density of 95% or more and a piezoelectric constant of 700 pC/N or more. For example, the other of the plurality of material layers 12-1a to 12-1d can include a BT-based piezoelectric material. For example, the BT-based piezoelectric material can include (Ba,Ca)TiO₃—Ba(Ti,Zr)O₃, but embodiments of the present disclosure are not limited thereto. The other of the plurality of material layers 12-1a to 12-1d can be configured or implemented to enhance or improve the reliability of the piezoelectric device 1. For example, the second material layer 12-1b and the fourth material layer 12-1d of the plurality of material layers 12-1a to 12-1d included in the second-1 material portion 12-1 can include a BT-based piezoelectric material, but embodiments of the present disclosure are not limited thereto.

Each of the plurality of material layers 11-1a to 11-1d included in the first-1 material portion 11-1 and the plurality of material layers 12-1a to 12-1d included in the second-1 material portion 12-1 can be individually formed through a tape casting process.

The plurality of material layers 11-1a to 11-1d included in the first-1 material portion 11-1 can be provided or implemented to be sequentially stacked. For example, the first material layer 11-1a of the first-1 material portion 11-1 can be disposed at a first surface (or an upper surface) of the second electrode layer 22. The first material layer 11-1a can include one of the KNN-based piezoelectric material and the BT-based piezoelectric material. For example, the first material layer 11-1a can include the BT-based piezoelectric material. Also, the second material layer 11-1b of the first-1 material portion 11-1 can be disposed at a first surface (or an upper surface) of the first material layer 11-1a. The second material layer 11-1b can include one of the KNN-based piezoelectric material and the BT-based piezoelectric material. For example, the second material layer 11-1b can include the KNN-based piezoelectric material which differs from the piezoelectric material of the first material layer 11-1a. Also, a third material layer 11-1c of the first-1 material portion 11-1 can be disposed at a first surface (or an upper surface) of the second material layer 11-1b. The third material layer 11-1c can include one of the KNN-based piezoelectric material and the BT-based piezoelectric material. For example, the third material layer 11-1c can include the BT-based piezoelectric material which differs from the piezoelectric material of the second material layer 11-1b. Also, the fourth material layer 11-1d of the first-1 material portion 11-1 can be disposed at a first surface (or an upper surface) of the third material layer 11-1c. The fourth material layer 11-1d can include one of the KNN-based piezoelectric material and the BT-based piezoelectric material. For example, the fourth material layer 11-1d can include the KNN-based piezoelectric material which differs from the piezoelectric material of the third material layer 11-1c. Also, the first electrode layer 21 can be disposed at a first surface (or an upper surface) of the fourth material layer 11-1d.

The plurality of material layers 12-1a to 12-1d included in the second-1 material portion 12-1 can be provided or implemented to be sequentially stacked. For example, the first material layer 12-1a of the second-1 material portion 12-1 can be disposed at a first surface (or an upper surface) of the second electrode layer 22. The first material layer 12-1a can include one of the KNN-based piezoelectric material and the BT-based piezoelectric material. For example, the first material layer 12-1a can include the KNN-based piezoelectric material. Also, the second material layer 12-1b of the second-1 material portion 12-1 can be disposed at a first surface (or an upper surface) of the first material layer 12-1a. The second material layer 12-1b can include one of the KNN-based piezoelectric material and the BT-based piezoelectric material. For example, the second material layer 12-1b can include the BT-based piezoelectric material which differs from the piezoelectric material of the first material layer 12-1a. Also, a third material layer 12-1c of the second-1 material portion 12-1 can be disposed at a first surface (or an upper surface) of the second material layer 12-1b. The third material layer 12-1c can include one of the KNN-based piezoelectric material and the BT-based piezoelectric material. For example, the third material layer 12-1c can include the KNN-based piezoelectric material which differs from the piezoelectric material of the second material layer 12-1b. Also, the fourth material layer 12-1d of the second-1 material portion 12-1 can be disposed at a first surface (or an upper surface) of the third material layer 12-1c. The fourth material layer 12-1d can include one of the KNN-based piezoelectric material and the BT-based piezoelectric material. For example, the fourth material layer 12-1d can include the BT-based piezoelectric material which differs from the piezoelectric material of the third material layer 12-1c. Also, the first electrode layer 21 can be disposed at a first surface (or an upper surface) of the fourth material layer 12-1d.

A process of manufacturing the piezoelectric device 1 according to an embodiment of the present disclosure will be described below.

First, each of the at least one first material portions 11-1 and 11-2 and the at least one second material portions 12-1 and 12-2 can be manufactured as a sheet having an appropriate thickness through an individual tape casting process. For example, a sheet of each of the at least one first material portions 11-1 and 11-2 can be formed by tape-casting a piezoelectric powder including a KNN-based piezoelectric material and a slurry including additives by using a tape casting apparatus (or a blade). Also, a sheet of each of the at least one second material portions 12-1 and 12-2 can be formed by tape-casting a piezoelectric powder including a BT-based piezoelectric material and a slurry including additives by using the tape casting apparatus (or the blade). For example, the one or more first material portions 11-1 and 11-2 can be represented by Chemical Formula 1 or Chemical Formula 2.

A sheet of at least one first material portions 11-1 and 11-2 and a sheet of at least one second material portions 12-1 and 12-2, individually manufactured by a tap casting process, can be disposed on the same plane in a predetermined sequence.

The placement (or arrangement) of the sheet of the at least one first material portions 11-1 and 11-2 and the sheet of the at least one second material portions 12-1 and 12-2 can be completed, and then, each material sheet can be stabilized by performing a warm isostatic press (WIP) process through primary molding. Also, a process of degreasing a primarily-molded green tape (or piezoelectric device layer) can be performed. A solvent or an organic material can be removed by a degreasing process. Then, a cold isostatic press (CIP) process can be performed through secondary molding. The CIP process can be used for increasing a density in a sintering process.

Subsequently, a sinter or the first vibration portion 11 and the second vibration portion 12 can be manufactured by sintering a green tape of each of the sheet of the at least one first material portions 11-1 and 11-2 and the sheet of the at least one second material portions 12-1 and 12-2.

According to an embodiment of the present disclosure, the sheets of the at least one first material portions 11-1 and 11-2 and the sheets of the at least one second material portions 12-1 and 12-2 having different characteristics can be provided in the sinter or the first vibration portion 11 and the second vibration portion 12, and thus, the sheets of the at least one first material portions 11-1 and 11-2 and the sheets of the at least one second material portions 12-1 and 12-2 can have different melting points, whereby it can be difficult to perform a sintering process under the same temperature condition.

Therefore, in a process of manufacturing the piezoelectric device 1 according to an embodiment of the present disclosure, a slurry of each of the at least one first material portions 11-1 and 11-2 can further include an additive (or a sintering agent). For example, the additive can include one or more of CuO, Fe₂O₃, La₂O₃, ZrO₂, ZnO, SnO₂, CdO, MnO₂, CuNb₂₀₆, Gd₂O₃, Al₂O₃, CaO, BaO, HfO, TiO₂, Co₂O₃, NiO, MgO, B₂O₃, and SiO₂. The additive can adjust a sintering temperature of the at least one first material portions 11-1 and 11-2. For example, in a case where the additive is not added, the sintering temperature of the at least one first material portions 11-1 and 11-2 can have a temperature period of 1,250° C. to 1,400° C., and in a case where the additive is added, the sintering temperature of the at least one first material portions 11-1 and 11-2 can have a temperature period of 1,090° C. to 1,200° C.

Also, a slurry of each of the at least one second material portions 12-1 and 12-2 can further include a first additive and a second additive. For example, the first additive can include one or more of CuO, Fe₂O₃, La₂O₃, ZrO₂, ZnO, SnO₂, CdO, MnO₂, CuNb₂O₆, Gd₂O₃, Al₂O₃, CaO, BaO, HfO, TiO₂, Co₂O₃, NiO, MgO, B₂O₃, and SiO₂. For example, the first additive can include one or more of CaCl₂), AlF₃, BaCl₂, LiF, MgF₂, CaF₂, NaF, KF, NaCl, MgCl₂, KCl, ZnCl₂, LiCl₂, AlCl₃, CaSO₄, CaSO₃, Na₂SO₄, Na₂SO₃, and Na₂S. The first additive and the second additive can adjust a sintering temperature of the at least one second material portions 12-1 and 12-2. For example, in a case where the first additive and the second additive are not added, the sintering temperature of the at least one second material portions 12-1 and 12-2 can have a temperature period of 1,450° C. or more. Also, in a case where the first additive is added, the sintering temperature of the at least one second material portions 12-1 and 12-2 can have a temperature period of 1,250° C. to 1,400° C., and in a case where the second additive is added, the sintering temperature of the at least one second material portions 12-1 and 12-2 can have a temperature period of 1,090° C. to 1,200° C. Because the additives are added to the at least one first material portions 11-1 and 11-2 and the at least one second material portions 12-1 and 12-2, the sintering temperatures of the at least one first material portions 11-1 and 11-2 and the at least one second material portions 12-1 and 12-2 can be adjusted similarly, and a sintering process can be performed under the same condition.

According to an embodiment of the present disclosure, the sheets of the at least one first material portions 11-1 and 11-2 can be molded by using a slurry including no additive, and the sheets of the at least one second material portions 12-1 and 12-2 can be molded by using a slurry including the first additive including one or more of CuO, Fe₂O₃, La₂O₃, ZrO₂, ZnO, SnO₂, CdO, MnO₂, CuNb₂O₆, Gd₂O₃, Al₂O₃, CaO, BaO, HfO, TiO₂, Co₂O₃, NiO, MgO, B₂O₃, and SiO₂. For example, the first additive can be added by 0.1 wt % to 1.0 wt %, but embodiments of the present disclosure are not limited thereto. In this case, a green tape where the sheets of the at least one first material portions 11-1 and 11-2 and the sheets of the at least one second material portions 12-1 and 12-2 are stacked can be put into an electric furnace, sintered in a temperature range of 1,250° C. to 1,400° C., and naturally cooled at a room temperature, thereby manufacturing the piezoelectric device 1. For example, a sintering temperature can increase at a speed of 5° C./min and a sintering maintenance time can be 2 hours to 8 hours, but embodiments of the present disclosure are not limited thereto. According to an embodiment of the present disclosure, a sintering temperature of each of the at least one first material portions 11-1 and 11-2 and the at least one second material portions 12-1 and 12-2 can have a similar temperature range of 1,250° C. to 1,400° C., and thus, a sintering process can be simultaneously performed under the same temperature condition.

According to another embodiment of the present disclosure, the sheets of the at least one first material portions 11-1 and 11-2 can be molded by using a slurry to which the additive including one or more of CuO, Fe₂O₃, La₂O₃, ZrO₂, ZnO, SnO₂, CdO, MnO₂, CuNb₂O₆, Gd₂O₃, Al₂O₃, CaO, BaO, HfO, TiO₂, Co₂O₃, NiO, MgO, B₂O₃, and SiO₂ is added by 0.5 wt %, and the sheets of the at least one second material portions 12-1 and 12-2 can be molded by using a slurry to which the second additive including one or more of CaCl₂), AlF₃, BaCl₂, LiF, MgF₂, CaF₂, NaF, KF, NaCl, MgCl₂, KCl, ZnCl₂, LiCl₂, AlCl₃, CaSO₄, CaSO₃, Na₂SO₄, Na₂SO₃, and Na₂S is added by 0.1 wt % to 2.0 wt %, but embodiments of the present disclosure are not limited thereto. The second additive included in the at least one second material portions 12-1 and 12-2 can be adjusted to be similar to the sintering temperature of each of the at least one first material portions 11-1 and 11-2 by doping fluoride and/or chloride in addition to metal oxide, so as to increase a diffusion speed from a low temperature. A green tape where the sheets of the at least one first material portions 11-1 and 11-2 and the sheets of the at least one second material portions 12-1 and 12-2 are stacked can be put into an electric furnace, sintered in a temperature range of 1,090° C. to 1,200° C., and naturally cooled at a room temperature, thereby manufacturing the sinter or the piezoelectric device 1. For example, a sintering temperature can increase at a speed of 5° C./min and a sintering maintenance time can be 2 hours to 8 hours, but embodiments of the present disclosure are not limited thereto. According to another embodiment of the present disclosure, a sintering temperature of each of the at least one first material portions 11-1 and 11-2 and the at least one second material portions 12-1 and 12-2 can have a similar temperature range of 1,090° C. to 1,200° C., and thus, a sintering process can be simultaneously performed under the same temperature condition.

Subsequently, the first electrode layer 21 and the second electrode layer 22 can be formed in the sinter or the piezoelectric device 1, and the piezoelectric device 1 can be manufactured through a polarization (or poling) process.

In the piezoelectric device 1 according to an embodiment of the present disclosure, the first vibration portion 11 and the second vibration portion 12 corresponding to a piezoelectric device layer can be without Pb, i.e., lead-free, and the reliability and driving characteristic of the piezoelectric device 1 can be enhanced or improved. Also, because the piezoelectric device 1 does not include Pb, a production restriction material can be reduced and replacement of a harmful material can be implemented, and thus, an environment-friendly piezoelectric device 1 and an apparatus including the same can be implemented or realized.

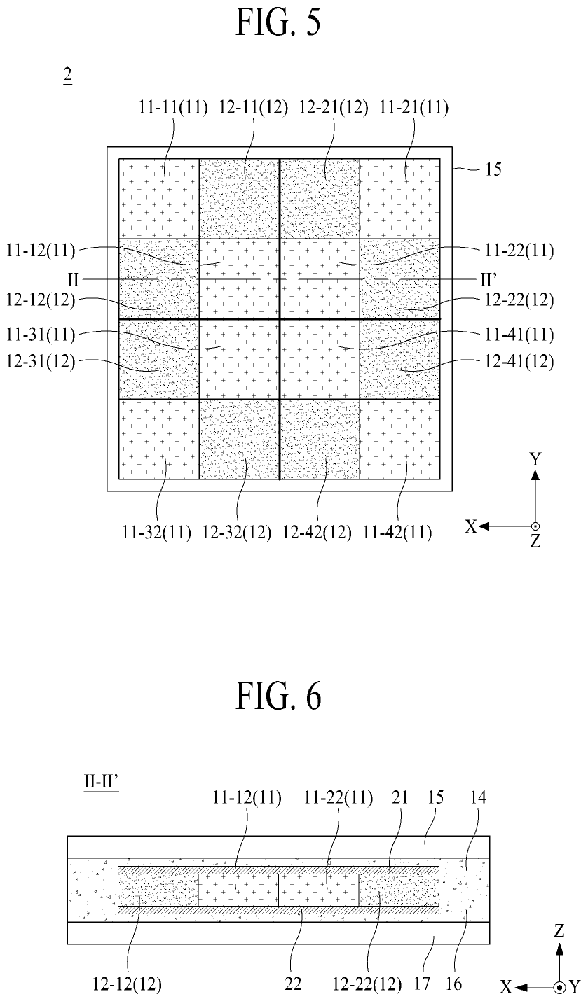

FIG. 5 illustrates a piezoelectric device according to another embodiment of the present disclosure. FIG. 6 is a cross-sectional view taken along line II-II′ of FIG. 5 according to another embodiment of the present disclosure. FIGS. 5 and 6 illustrate an embodiment implemented by modifying a configuration of the piezoelectric device 1 described above with reference to FIGS. 1 to 4. In the following description, therefore, the same elements other than a structure of a piezoelectric device and relevant elements are referred to by like reference numerals, and repeated descriptions thereof are omitted or will be briefly given.

Referring to FIGS. 5 and 6, a piezoelectric device 1 according to another embodiment of the present disclosure can include a first vibration portion 11, a second vibration portion 12, a first electrode layer 21, and a second electrode layer 22.

Each of the first vibration portion 11 and the second vibration portion 12 according to another embodiment of the present disclosure can include a plurality of material portions. For example, the first vibration portion 11 can include a plurality of first material portions 11-11, 11-12, 11-21, 11-22, 11-31, 11-32, 11-41, and 11-42. Also, the second vibration portion 12 can include a plurality of second material portions 12-11, 12-12, 12-21, 12-22, 12-31, 12-32, 12-41, and 12-42.

The plurality of first material portions 11-11, 11-12, 11-21, 11-22, 11-31, 11-32, 11-41, and 11-42 and the plurality of second material portions 12-11, 12-12, 12-21, 12-22, 12-31, 12-32, 12-41, and 12-42 can have different characteristics. For example, the plurality of first material portions 11-11, 11-12, 11-21, 11-22, 11-31, 11-32, 11-41, and 11-42 and the plurality of second material portions 12-11, 12-12, 12-21, 12-22, 12-31, 12-32, 12-41, and 12-42 can include piezoelectric materials having different characteristics. For example, the plurality of first material portions 11-11, 11-12, 11-21, 11-22, 11-31, 11-32, 11-41, and 11-42 and the plurality of second material portions 12-11, 12-12, 12-21, 12-22, 12-31, 12-32, 12-41, and 12-42 can include a Pb-free piezoelectric material. For example, the plurality of first material portions 11-11, 11-12, 11-21, 11-22, 11-31, 11-32, 11-41, and 11-42 and the plurality of second material portions 12-11, 12-12, 12-21, 12-22, 12-31, 12-32, 12-41, and 12-42 can include Pb-free piezoelectric materials having different characteristics.

According to an embodiment of the present disclosure, each of the plurality of first material portions 11-11, 11-12, 11-21, 11-22, 11-31, 11-32, 11-41, and 11-42 can include a piezoelectric material having one or more of a higher curie temperature and a less piezoelectric constant than each of the plurality of second material portions 12-11, 12-12, 12-21, 12-22, 12-31, 12-32, 12-41, and 12-42.

Each of the plurality of first material portions 11-11, 11-12, 11-21, 11-22, 11-31, 11-32, 11-41, and 11-42 can have one or more of a relative density of 90% or more and a curie temperature of 170° C. or more. For example, each of the plurality of first material portions 11-11, 11-12, 11-21, 11-22, 11-31, 11-32, 11-41, and 11-42 can include a piezoelectric material which has a relative density of 90% or more and a curie temperature of 170° C. or more. For example, each of the plurality of first material portions 11-11, 11-12, 11-21, 11-22, 11-31, 11-32, 11-41, and 11-42 can include a KNN-based piezoelectric material including K, Na, and Nb. For example, the KNN-based piezoelectric material can include (K,Na)NbO₃, but embodiments of the present disclosure are not limited thereto. The plurality of first material portions 11-11, 11-12, 11-21, 11-22, 11-31, 11-32, 11-41, and 11-42 can be configured or implemented to enhance or improve the reliability of the piezoelectric device 1. For example, the plurality of first material portions 11-11, 11-12, 11-21, 11-22, 11-31, 11-32, 11-41, and 11-42 can be represented by Chemical Formula 1 or Chemical Formula 2, but embodiments of the present disclosure are not limited thereto.

Each of the plurality of second material portions 12-11, 12-12, 12-21, 12-22, 12-31, 12-32, 12-41, and 12-42 can have a relative density of 95% or more and a piezoelectric constant of 700 pC/N or more. For example, each of the plurality of second material portions 12-11, 12-12, 12-21, 12-22, 12-31, 12-32, 12-41, and 12-42 can include a piezoelectric material which has a relative density of 95% or more and a piezoelectric constant of 700 pC/N or more. For example, each of the plurality of second material portions 12-11, 12-12, 12-21, 12-22, 12-31, 12-32, 12-41, and 12-42 can include a BT-based piezoelectric material. For example, the BT-based piezoelectric material can include (Ba,Ca)TiO₃—Ba(Ti,Zr)O₃, but embodiments of the present disclosure are not limited thereto. The plurality of second material portions 12-11, 12-12, 12-21, 12-22, 12-31, 12-32, 12-41, and 12-42 can be configured or implemented to enhance or improve the reliability of the piezoelectric device 1.

According to an embodiment of the present disclosure, some 11-12, 11-22, 11-31, and 11-41 of the plurality of first material portions 11-11, 11-12, 11-21, 11-22, 11-31, 11-32, 11-41, and 11-42 can be configured at a center of the piezoelectric device 2. For example, the plurality of second material portions 12-11, 12-12, 12-21, 12-22, 12-31, 12-32, 12-41, and 12-42 can surround some first material portions 11-12, 11-22, 11-31, and 11-41. For example, the BT-based piezoelectric material can surround the KNN-based piezoelectric material. Accordingly, a vibration characteristic of the piezoelectric device 2 can be configured or implemented to enhance or improve.

According to an embodiment of the present disclosure, the reliability of the plurality of second material portions 12-11, 12-12, 12-21, 12-22, 12-31, 12-32, 12-41, and 12-42 can be complemented by a high relative density and/or a high curie temperature of the plurality of first material portions 11-11, 11-12, 11-21, 11-22, 11-31, 11-32, 11-41, and 11-42, and a low piezoelectric characteristic of the plurality of first material portions 11-11, 11-12, 11-21, 11-22, 11-31, 11-32, 11-41, and 11-42 can be complemented by the plurality of second material portions 12-11, 12-12, 12-21, 12-22, 12-31, 12-32, 12-41, and 12-42 having a high relative density and/or a high piezoelectric constant.

According to an embodiment of the present disclosure, the plurality of second material portions 12-11, 12-12, 12-21, 12-22, 12-31, 12-32, 12-41, and 12-42 can be configured adjacent to the plurality of first material portions 11-11, 11-12, 11-21, 11-22, 11-31, 11-32, 11-41, and 11-42. For example, the BT-based piezoelectric material can be configured adjacent to the KNN-based piezoelectric material. For example, the plurality of first material portions 11-11, 11-12, 11-21, 11-22, 11-31, 11-32, 11-41, and 11-42 can be configured adjacent to the plurality of second material portions 12-11, 12-12, 12-21, 12-22, 12-31, 12-32, 12-41, and 12-42 to have an equal area. For example, the KNN-based piezoelectric material can be configured adjacent to the BT-based piezoelectric material to have an equal area. Because the KNN-based piezoelectric material is configured adjacent to the BT-based piezoelectric material to have an equal area, a degradation in the piezoelectric device 2 caused by a low curie temperature of the BT-based piezoelectric material can be prevented or reduced, and thus, the reliability of the piezoelectric device 2 can be enhanced, thereby enhancing a vibration characteristic of the piezoelectric device 2 based on a high piezoelectric constant of the BT-based piezoelectric material.

The plurality of first material portions 11-11, 11-12, 11-21, 11-22, 11-31, 11-32, 11-41, and 11-42 and the plurality of second material portions 12-11, 12-12, 12-21, 12-22, 12-31, 12-32, 12-41, and 12-42 according to an embodiment of the present disclosure can have the same thickness or different thicknesses. For example, the plurality of first material portions 11-11, 11-12, 11-21, 11-22, 11-31, 11-32, 11-41, and 11-42 and the plurality of second material portions 12-11, 12-12, 12-21, 12-22, 12-31, 12-32, 12-41, and 12-42 can have substantially the same height within an error range of a manufacturing process. Also, the plurality of first material portions 11-11, 11-12, 11-21, 11-22, 11-31, 11-32, 11-41, and 11-42 and the plurality of second material portions 12-11, 12-12, 12-21, 12-22, 12-31, 12-32, 12-41, and 12-42 can have the same size or different sizes. For example, the plurality of first material portions 11-11, 11-12, 11-21, 11-22, 11-31, 11-32, 11-41, and 11-42 and the plurality of second material portions 12-11, 12-12, 12-21, 12-22, 12-31, 12-32, 12-41, and 12-42 can have substantially the same size within an error range of a manufacturing process. Also, the number of first material portions 11-11, 11-12, 11-21, 11-22, 11-31, 11-32, 11-41, and 11-42 can be equal to or different from the number of second material portions 12-11, 12-12, 12-21, 12-22, 12-31, 12-32, 12-41, and 12-42. For example, the number of first material portions 11-11, 11-12, 11-21, 11-22, 11-31, 11-32, 11-41, and 11-42 can be equal to the number of second material portions 12-11, 12-12, 12-21, 12-22, 12-31, 12-32, 12-41, and 12-42. For example, the plurality of first material portions 11-11, 11-12, 11-21, 11-22, 11-31, 11-32, 11-41, and 11-42 can include a first-11 material portion 11-11, a first-12 material portion 11-12, a first-21 material portion 11-21, a first-22 material portion 11-22, a first-31 material portion 11-31, a first-32 material portion 11-32, a first-41 material portion 11-41, and a first-11 material portion 11-42. Also, the plurality of second material portions 12-11, 12-12, 12-21, 12-22, 12-31, 12-32, 12-41, and 12-42 can include a second-11 material portion 12-11, a second-12 material portion 12-12, a second-21 material portion 12-21, a second-22 material portion 12-22, a second-31 material portion 12-31, a second-32 material portion 12-32, a second-41 material portion 12-41, and a second-42 material portion 12-42.

Each of the plurality of first material portions 11-11, 11-12, 11-21, 11-22, 11-31, 11-32, 11-41, and 11-42 and the plurality of second material portions 12-11, 12-12, 12-21, 12-22, 12-31, 12-32, 12-41, and 12-42 can include a tetragonal shape which has a first length parallel to a first direction X and a second length parallel to a second direction Y intersecting with the first direction X. For example, each of the plurality of first material portions 11-11, 11-12, 11-21, 11-22, 11-31, 11-32, 11-41, and 11-42 and the plurality of second material portions 12-11, 12-12, 12-21, 12-22, 12-31, 12-32, 12-41, and 12-42 can include a square shape where the first length is equal to the second length, but embodiments of the present disclosure are not limited thereto.

The plurality of first material portions 11-11, 11-12, 11-21, 11-22, 11-31, 11-32, 11-41, and 11-42 and the plurality of second material portions 12-11, 12-12, 12-21, 12-22, 12-31, 12-32, 12-41, and 12-42 can be arranged adjacent to each other in the first direction X or the second direction Y in the same plane. For example, the first-1 material portion 11-1 and the second-1 material portion 12-1 can be arranged adjacent to each other in the first direction X. The first-11 material portion 11-11, the second-11 material portion 12-11, the second-21 material portion 12-21, and the first-21 material portion 11-21 can be sequentially arranged in the first direction X and can be arranged in parallel in the second direction Y. Also, the second-12 material portion 12-12, the first-12 material portion 11-12, the first-22 material portion 11-22, and the second-22 material portion 12-22 can be sequentially arranged in the first direction X and can be arranged in parallel in the second direction Y. Also, the second-31 material portion 12-31, the first-31 material portion 11-31, the first-41 material portion 11-41, and the second-41 material portion 12-41 can be sequentially arranged in the first direction X and can be arranged in parallel in the second direction Y. Also, the first-32 material portion 11-32, the second-32 material portion 12-32, the second-42 material portion 12-42, and the first-42 material portion 11-42 can be sequentially arranged in the first direction X and can be arranged in parallel in the second direction Y.

According to an embodiment of the present disclosure, the reliability of the plurality of second material portions 12-11, 12-12, 12-21, 12-22, 12-31, 12-32, 12-41, and 12-42 can be complemented based on a high relative density and/or a high curie temperature of the plurality of first material portions 11-11, 11-12, 11-21, 11-22, 11-31, 11-32, 11-41, and 11-42, and a low piezoelectric characteristic of the plurality of first material portions 11-11, 11-12, 11-21, 11-22, 11-31, 11-32, 11-41, and 11-42 can be complemented by the plurality of second material portions 12-11, 12-12, 12-21, 12-22, 12-31, 12-32, 12-41, and 12-42 having a high relative density and/or a high piezoelectric constant.

According to an embodiment of the present disclosure, the plurality of second material portions 12-11, 12-12, 12-21, 12-22, 12-31, 12-32, 12-41, and 12-42 can be provided adjacent to the plurality of first material portions 11-11, 11-12, 11-21, 11-22, 11-31, 11-32, 11-41, and 11-42. For example, the KNN-based piezoelectric material can be configured adjacent to the BT-based piezoelectric material. Because the KNN-based piezoelectric material is configured adjacent to the BT-based piezoelectric material, a degradation in the piezoelectric device 2 caused by a low curie temperature of the BT-based piezoelectric material can be prevented, and thus, the reliability of the piezoelectric device 2 can be enhanced, thereby enhancing a vibration characteristic of the piezoelectric device 2 based on a high piezoelectric constant of the BT-based piezoelectric material.

Each of the plurality of first material portions 11-11, 11-12, 11-21, 11-22, 11-31, 11-32, 11-41, and 11-42 and the plurality of second material portions 12-11, 12-12, 12-21, 12-22, 12-31, 12-32, 12-41, and 12-42 can be individually formed through a tape casting process. The plurality of first material portions 11-11, 11-12, 11-21, 11-22, 11-31, 11-32, 11-41, and 11-42 and the plurality of second material portions 12-11, 12-12, 12-21, 12-22, 12-31, 12-32, 12-41, and 12-42 can be arranged or configured as a matrix type on the same plane to have an equal area.

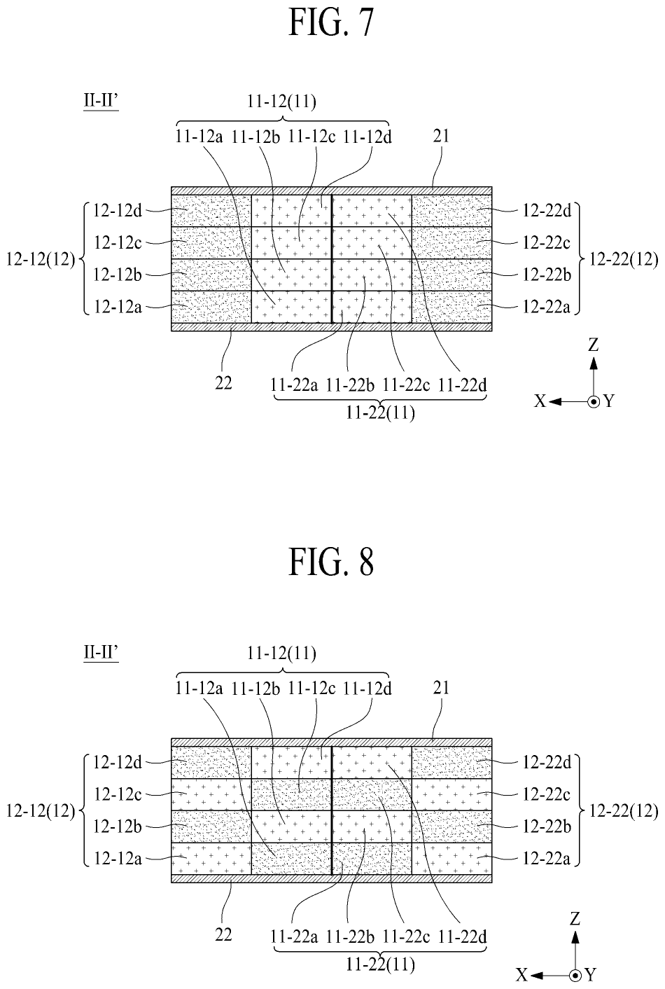

FIGS. 7 and 8 illustrate another structure of the piezoelectric device of FIG. 6 according to another embodiment of the present disclosure. FIGS. 7 and 8 illustrate another structure of the piezoelectric device 2 described above with reference to FIGS. 5 and 6. In the following description, therefore, the same elements other than a structure of a piezoelectric device and relevant elements are referred to by like reference numerals, and repeated descriptions thereof are omitted or will be briefly given.

Each of the first vibration portion 11 and the second vibration portion 12 can include a plurality of material layers which overlap each other in a thickness direction Z. For example, with respect to a second column of a matrix type illustrated in FIG. 6, the first-12 material portion 11-12 of the first vibration portion 11 can include a plurality of material layers 11-12a, 11-12b, 11-12c, and 11-12d, and the first-22 material portion 11-22 of the first vibration portion 11 can include a plurality of material layers 11-22a, 11-22b, 11-22c, and 11-22d. Also, the second-12 material portion 12-12 of the second vibration portion 12 can include a plurality of material layers 12-12a, 12-12b, 12-12c, and 12-12d, and the second-22 material portion 12-22 of the second vibration portion 12 can include a plurality of material layers 12-22a, 12-22b, 12-22c, and 12-22d. For example, the first-12 material portion 11-12 can include a first material layer 11-12a, a second material layer 11-12b, a third material layer 11-12c, and a fourth material layer 11-12d, but embodiments of the present disclosure are not limited thereto. Also, the first-22 material portion 11-22 can include a first material layer 11-22a, a second material layer 11-22b, a third material layer 11-22c, and a fourth material layer 11-22d, but embodiments of the present disclosure are not limited thereto. Also, the second-12 material portion 12-12 can include a first material layer 12-12a, a second material layer 12-12b, a third material layer 12-12c, and a fourth material layer 12-12d, but embodiments of the present disclosure are not limited thereto. Also, the second-22 material portion 12-22 can include a first material layer 12-22a, a second material layer 12-22b, a third material layer 12-22c, and a fourth material layer 12-22d, but embodiments of the present disclosure are not limited thereto.

According to an embodiment of the present disclosure, as illustrated in FIG. 7, each of a plurality of material layers 11-12a, 11-12b, 11-12c, and 11-12d included in the first-12 material portion 11-12 can include the same piezoelectric material. Each of a plurality of material layers 11-22a, 11-22b, 11-22c, and 11-22d included in the first-22 material portion 11-22 can include the same piezoelectric material. For example, each of the plurality of material layers 11-12a, 11-12b, 11-12c, and 11-12d included in the first-12 material portion 11-12 can include the KNN-based piezoelectric material. For example, each of the plurality of material layers 11-22a, 11-22b, 11-22c, and 11-22d included in the first-22 material portion 11-22 can include the KNN-based piezoelectric material. As another example, each of the plurality of material layers 11-12a, 11-12b, 11-12c, and 11-12d included in the first-12 material portion 11-12 can include the BT-based piezoelectric material. For example, each of the plurality of material layers 11-22a, 11-22b, 11-22c, and 11-22d included in the first-22 material portion 11-22 can include the BT-based piezoelectric material. Also, each of a plurality of material layers 12-12a, 12-12b, 12-12c, and 12-12d included in the second-12 material portion 12-12 can include the same piezoelectric material. Each of a plurality of material layers 12-22a, 12-22b, 12-22c, and 12-22d included in the second-22 material portion 12-22 can include the same piezoelectric material. For example, each of the plurality of material layers 12-12a, 12-12b, 12-12c, and 12-12d included in the second-12 material portion 12-12 can include the BT-based piezoelectric material. For example, each of the plurality of material layers 12-22a, 12-22b, 12-22c, and 12-22d included in the second-22 material portion 12-22 can include the BT-based piezoelectric material. As another example, each of the plurality of material layers 12-12a, 12-12b, 12-12c, and 12-12d included in the second-12 material portion 12-12 can include the KNN-based piezoelectric material. Each of the plurality of material layers 12-22a, 12-22b, 12-22c, and 12-22d included in the second-22 material portion 12-22 can include the KNN-based piezoelectric material. According to an embodiment of the present disclosure, in a case where the KNN-based piezoelectric material is disposed outside the BT-based piezoelectric material, a degradation in the piezoelectric device 1 caused by a low curie temperature of the BT-based piezoelectric material can be prevented, and thus, the reliability of the piezoelectric device 1 can be enhanced.

Each of the plurality of material layers 11-12a, 11-12b, 11-12c, and 11-12d included in the first-12 material portion 11-12, the plurality of material layers 11-22a, 11-22b, 11-22c, and 11-22d included in the first-22 material portion 11-22, the plurality of material layers 12-12a, 12-12b, 12-12c, and 12-12d included in the second-12 material portion 12-12, and the plurality of material layers 12-22a, 12-22b, 12-22c, and 12-22d included in the second-22 material portion 12-22 can be individually formed through a tape casting process and can be configured or implemented to be sequentially stacked. According to another embodiment of the present disclosure, as illustrated in FIG. 8, the plurality of material layers 11-12a, 11-12b, 11-12c, and 11-12d included in the first-12 material portion 11-12 can include different piezoelectric materials. For example, some of the plurality of material layers 11-12a, 11-12b, 11-12c, and 11-12d can include the same piezoelectric material, and the other of the plurality of material layers 11-12a, 11-12b, 11-12c, and 11-12d can include different piezoelectric materials. Some of the plurality of material layers 11-12a, 11-12b, 11-12c, and 11-12d can include the KNN-based piezoelectric material. For example, the plurality of material layers 11-12b and 11-12d can include the KNN-based piezoelectric material. The other of the plurality of material layers 11-12a, 11-12b, 11-12c, and 11-12d can include the BT-based piezoelectric material. For example, the plurality of material layers 11-12a and 11-12c can include the BT-based piezoelectric material. The plurality of material layers 11-22a, 11-22b, 11-22c, and 11-22d included in the first-22 material portion 11-22 can include different piezoelectric materials. For example, some of the plurality of material layers 11-22a, 11-22b, 11-22c, and 11-22d can include the same piezoelectric material, and the other of the plurality of material layers 11-22a, 11-22b, 11-22c, and 11-22d can include different piezoelectric materials. Some of the plurality of material layers 11-22a, 11-22b, 11-22c, and 11-22d can include the KNN-based piezoelectric material. For example, the plurality of material layers 11-22b and 11-22d can include the KNN-based piezoelectric material. The plurality of material layers 11-22b and 11-22d can include the BT-based piezoelectric material. For example, the plurality of material layers 11-22a and 11-22c can include the BT-based piezoelectric material. The plurality of material layers 12-12a, 12-12b, 12-12c, and 12-12d included in the second-12 material portion 12-12 can include different piezoelectric materials. For example, some of the plurality of material layers 12-12a, 12-12b, 12-12c, and 12-12d can include the same piezoelectric material, and the other of the plurality of material layers 12-12a, 12-12b, 12-12c, and 12-12d can include different piezoelectric materials. Some of the plurality of material layers 12-12a, 12-12b, 12-12c, and 12-12d can include the KNN-based piezoelectric material. For example, the plurality of material layers 12-12a and 12-12c can include the KNN-based piezoelectric material. The other of the plurality of material layers 12-12a, 12-12b, 12-12c, and 12-12d can include the BT-based piezoelectric material. For example, the plurality of material layers 12-12b and 12-12d can include the BT-based piezoelectric material. As another example, some of the plurality of material layers 12-12a, 12-12b, 12-12c, and 12-12d can include the BT-based piezoelectric material. For example, the plurality of material layers 12-12a and 12-12c can include the BT-based piezoelectric material. The other of the plurality of material layers 12-12a, 12-12b, 12-12c, and 12-12d can include the KNN-based piezoelectric material. For example, the plurality of material layers 12-12b and 12-12d can include the KNN-based piezoelectric material. The plurality of material layers 12-22a, 12-22b, 12-22c, and 12-22d included in the second-22 material portion 12-22 can include different piezoelectric materials. For example, some of the plurality of material layers 12-22a, 12-22b, 12-22c, and 12-22d can include the same piezoelectric material, and the other of the plurality of material layers 12-22a, 12-22b, 12-22c, and 12-22d can include different piezoelectric materials. According to an embodiment of the present disclosure, in a case where the KNN-based piezoelectric material is disposed outside (for example, one or more of an upper side, a lower side, a left side, and a right side) the BT-based piezoelectric material, a degradation in the piezoelectric device 1 caused by a low curie temperature of the BT-based piezoelectric material can be prevented, and thus, the reliability of the piezoelectric device 1 can be enhanced

Each of the plurality of material layers 11-12a, 11-12b, 11-12c, and 11-12d included in the first-12 material portion 11-12, the plurality of material layers 11-22a, 11-22b, 11-22c, and 11-22d included in the first-22 material portion 11-22, the plurality of material layers 12-12a, 12-12b, 12-12c, and 12-12d included in the second-12 material portion 12-12, and the plurality of material layers 12-22a, 12-22b, 12-22c, and 12-22d included in the second-22 material portion 12-22 can be individually formed through a tape casting process and can be configured or implemented to be sequentially stacked. For example, each of the plurality of material layers 11-12a, 11-12b, 11-12c, and 11-12d included in the first-12 material portion 11-12, the plurality of material layers 11-22a, 11-22b, 11-22c, and 11-22d included in the first-22 material portion 11-22, the plurality of material layers 12-12a, 12-12b, 12-12c, and 12-12d included in the second-12 material portion 12-12, and the plurality of material layers 12-22a, 12-22b, 12-22c, and 12-22d included in the second-22 material portion 12-22 can include a piezoelectric material which differs from the other material layer upward or downward adjacent thereto.

Except for that a plurality of material portions are included in each of the first vibration portion 11 and the second vibration portion 12 of the piezoelectric device 2, a process of manufacturing the piezoelectric device 2 according to another embodiment of the present disclosure can be the same as the descriptions of FIGS. 1 to 4, and thus, repeated descriptions thereof are omitted. Also, with reference to FIGS. 1-8, the first vibration portion 11 can include a plurality of first material portions and the second vibration portion 12 includes a plurality of second material portions that are further arranged along at least a second direction Y that intersects the first direction X and a third or thickness direction Z that intersects both the first direction X and the second direction Y. Accordingly, the plurality of first material portions and the second material portions can be arranged side-by-side or can be stacked in at least one of the first direction X, the second direction Y and the third direction Z. But embodiments of the present disclosure are not limited thereto.

In the piezoelectric device 2 according to another embodiment of the present disclosure, the first vibration portion 11 and the second vibration portion 12 corresponding to a piezoelectric device layer can be without Pb, and the reliability and driving characteristic of the piezoelectric device 2 can be enhanced or improved. Also, because the piezoelectric device 2 does not include Pb, a production restriction material can be reduced and replacement of a harmful material can be implemented, and thus, an environment-friendly piezoelectric device 2 and an apparatus including the same can be implemented or realized.

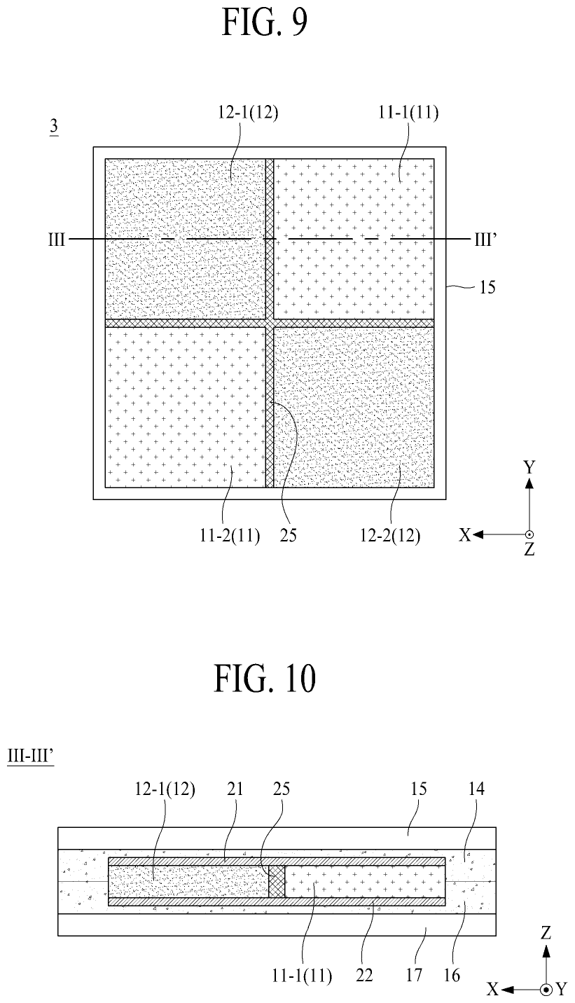

FIG. 9 illustrates a piezoelectric device 3 according to another embodiment of the present disclosure. FIG. 10 is a cross-sectional view taken along line III-III′ of FIG. 9 according to another embodiment of the present disclosure. FIGS. 9 and 10 illustrate another structure of the piezoelectric device 1 described above with reference to FIGS. 1 to 4. In the following description, therefore, the same elements other than a structure of a coupling member and relevant elements are referred to by like reference numerals, and repeated descriptions thereof are omitted or will be briefly given.

Referring to FIGS. 9 and 10, the piezoelectric device 3 according to another embodiment of the present disclosure can further include a coupling member 25.

A first vibration portion 11 and a second vibration portion 12 of the piezoelectric device 3 according to another embodiment of the present disclosure can be configured apart from each other on the same plane. For example, the first vibration portion 11 and the second vibration portion 12 can be configured apart from an adjacent vibration portion by a certain interval. For example, a separation distance between the first vibration portion 11 and the second vibration portion 12 can be less than 3 mm, but embodiments of the present disclosure are not limited thereto. When the separation distance between the first vibration portion 11 and the second vibration portion 12 is more than 3 mm, a sound characteristic can be reduced by resonance interference.

Each of the first vibration portion 11 and the second vibration portion 12 of the piezoelectric device 3 according to another embodiment of the present disclosure can include one or more material portions. For example, the first vibration portion 11 can include one or more first material portions 11-1 and 11-2. Also, the second vibration portion 12 can include one or more second material portions 12-1 and 12-2. The one or more first material portions 11-1 and 11-2 and the one or more second material portions 12-1 and 12-2 can have different characteristics. For example, the one or more first material portions 11-1 and 11-2 and the one or more second material portions 12-1 and 12-2 can include Pb-free piezoelectric materials having different characteristics. For example, the one or more first material portions 11-1 and 11-2 can include the KNN-based piezoelectric material, but embodiments of the present disclosure are not limited thereto. For example, the one or more second material portions 12-1 and 12-2 can include the BT-based piezoelectric material, but embodiments of the present disclosure are not limited thereto.

The one or more first material portions 11-1 and 11-2 and the one or more second material portions 12-1 and 12-2 according to another embodiment of the present disclosure can be configured apart from each other by a certain interval.

The one or more first material portions 11-1 and 11-2 and the one or more second material portions 12-1 and 12-2 can be arranged apart from each other by a certain interval in a first direction X or a second direction Y on the same plane. For example, a first-1 material portion 11-1 and a second-1 material portion 12-1 can be arranged apart from each other by a certain interval in a first direction X. The first-1 material portion 11-1 and the second-1 material portion 12-1 can be arranged in parallel in the second direction Y. Also, the first-1 material portion 11-1 can be disposed apart from the second-1 material portion 12-1 at a right periphery of the second-1 material portion 12-1, and the second-1 material portion 12-1 can be disposed apart from the first-1 material portion 11-1 at a left periphery of the first-1 material portion 11-1. Also, the second-2 material portion 12-2 and the first-2 material portion 11-2 can be disposed apart from each other by a certain interval in the first direction X. The second-2 material portion 12-2 and the first-2 material portion 11-2 can be disposed in parallel in the first direction X. Also, the second-2 material portion 12-2 can be disposed apart from the first-2 material portion 11-2 at a right periphery of the first-2 material portion 11-2, and the first-2 material portion 11-2 can be disposed apart from the second-2 material portion 12-2 at a left periphery of the second-2 material portion 12-2. Also, the first-1 material portion 11-1 and the second-2 material portion 12-2 can be disposed apart from each other by a certain interval in the second direction Y. The first-1 material portion 11-1 and the second-2 material portion 12-2 can be disposed in parallel in the first direction X. Also, the first-1 material portion 11-1 can be disposed apart from the second-2 material portion 12-2 at an upper periphery of the second-2 material portion 12-2, and the second-2 material portion 12-2 can be disposed apart from the first-1 material portion 11-1 at a lower periphery of the first-1 material portion 11-1. Also, the second-1 material portion 12-1 and the first-2 material portion 11-2 can be disposed apart from each other by a certain interval in the second direction Y. The second-1 material portion 12-1 and the first-2 material portion 11-2 can be disposed in parallel in the first direction X. Also, the second-1 material portion 12-1 can be disposed apart from the first-2 material portion 11-2 at an upper periphery of the first-2 material portion 11-2, and the first-2 material portion 11-2 can be disposed apart from the second-1 material portion 12-1 at a lower periphery of the second-1 material portion 12-1.

The coupling member 25 can be disposed or provided in a separation space between the one or more first material portions 11-1 and 11-2 and the one or more second material portions 12-1 and 12-2.

The coupling member 25 can be disposed between the one or more first material portions 11-1 and 11-2 and the one or more second material portions 12-1 and 12-2. For example, the coupling member 25 can be disposed between the first-1 material portion 11-1 and the second-1 material portion 12-1. Also, the coupling member 25 can be disposed between the second-2 material portion 12-2 and the first-2 material portion 11-2. Also, the coupling member 25 can be disposed between the first-1 material portion 11-1 and the second-2 material portion 12-2. Also, the coupling member 25 can be disposed between the second-1 material portion 12-1 and the first-2 material portion 11-2. For example, the coupling member 25 can be disposed or configured in a “+”-shape between the one or more first material portions 11-1 and 11-2 and the one or more second material portions 12-1 and 12-2.

Material portions, which are spaced apart from each other and are adjacent to each other, of each of the one or more first material portions 11-1 and 11-2 and the one or more second material portions 12-1 and 12-2 can be coupled to or connected with each other by the coupling member 25. For example, the first-1 material portion 11-1 and the second-1 material portion 12-1 can be coupled to or connected with each other by the coupling member 25. Also, the second-2 material portion 12-2 and the first-2 material portion 11-2 can be coupled to or connected with each other by the coupling member 25. Also, the first-1 material portion 11-1 and the second-2 material portion 12-2 can be coupled to or connected with each other by the coupling member 25. Also, the second-1 material portion 12-1 and the first-2 material portion 11-2 can be coupled to or connected with each other by the coupling member 25.

The coupling member 25 can include an adhesive or an adhesive resin, but embodiments of the present disclosure are not limited thereto. For example, the coupling member 25 can include epoxy, acryl, silicone, or urethane, but embodiments of the present disclosure are not limited thereto.

A process of manufacturing the piezoelectric device 3 according to an embodiment of the present disclosure will be described below.

First, each of the at least one first material portions 11-1 and 11-2 and the at least one second material portions 12-1 and 12-2 can be manufactured as a sheet having an appropriate thickness through an individual tape casting process. For example, a sheet of each of the at least one first material portions 11-1 and 11-2 can be formed by tape-casting a piezoelectric powder including a KNN-based piezoelectric material and a slurry including additives by using a tape casting apparatus (or a blade). Also, a sheet of each of the at least one second material portions 12-1 and 12-2 can be formed by tape-casting a piezoelectric powder including a BT-based piezoelectric material and a slurry including additives by using the tape casting apparatus (or the blade). For example, the one or more first material portions 11-1 and 11-2 can be represented by Chemical Formula 1 or Chemical Formula 2.

Each material sheet can be stabilized by performing a WIP process on each of the sheet of the at least one first material portions 11-1 and 11-2 and the sheet of the at least one second material portions 12-1 and 12-2, which are individually manufactured by tape casting. Also, a process of degreasing a primarily-molded green tape (or piezoelectric device layer) can be performed. A solvent or an organic material can be removed by a degreasing process. Then, a CIP process can be performed through secondary molding. The CIP process can be used for increasing a density in a sintering process.

Subsequently, a sinter or the at least one first material portions 11-1 and 11-2 of the first vibration portion 11 and the at least one second material portions 12-1 and 12-2 of the second vibration portion 12 can be individually manufactured by sintering a sinter or the sheet of the at least one first material portions 11-1 and 11-2 and the sheet of the at least one second material portions 12-1 and 12-2.

According to another embodiment of the present disclosure, an individual sintering process can be performed on each of the sheet of the at least one first material portions 11-1 and 11-2 and the sheet of the at least one second material portions 12-1 and 12-2 having different characteristics, and thus, because it is needed to perform a sintering process based on the same temperature condition, separate additives for adjusting a sintering temperature may not be added.

The sintered at least one first material portions 11-1 and 11-2 and at least one second material portions 12-1 and 12-2 can be disposed on the same plane in a predetermined sequence. The at least one first material portions 11-1 and 11-2 and the at least one second material portions 12-1 and 12-2 can be arranged apart from each other by a certain interval.

The coupling member 25 can be filled between the at least one first material portions 11-1 and 11-2 and the at least one second material portions 12-1 and 12-2 and can be cured (or dried) within a temperature range of about 200° C., but embodiments of the present disclosure are not limited thereto. Also, a process of removing foreign materials caused by the coupling member 25 can be additionally performed.

Subsequently, the first electrode layer 21 and the second electrode layer 22 can be formed in the piezoelectric device 1 or the sinter coupled by the coupling member 25, and the piezoelectric device 1 can be manufactured by a polarization (or poling) process.

In the piezoelectric device 3 according to an embodiment of the present disclosure, the first vibration portion 11 and the second vibration portion 12 corresponding to a piezoelectric device layer can be without Pb, and the reliability and driving characteristic of the piezoelectric device 1 can be enhanced or improved. Also, because the piezoelectric device 1 does not include Pb, a production restriction material can be reduced and replacement of a harmful material can be implemented, and thus, an environment-friendly piezoelectric device 1 and an apparatus including the same can be implemented or realized. In the piezoelectric device 3 according to an embodiment of the present disclosure, a separate process or additives for adjusting a sintering temperature of piezoelectric materials having different characteristics may not be provided, and thus, optimization of a manufacturing process can be implemented, thereby decreasing time and cost and enhancing productivity.

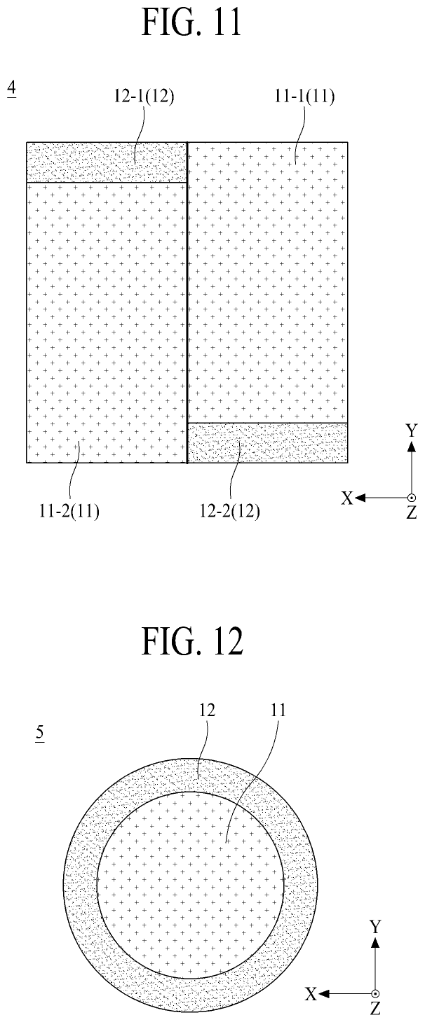

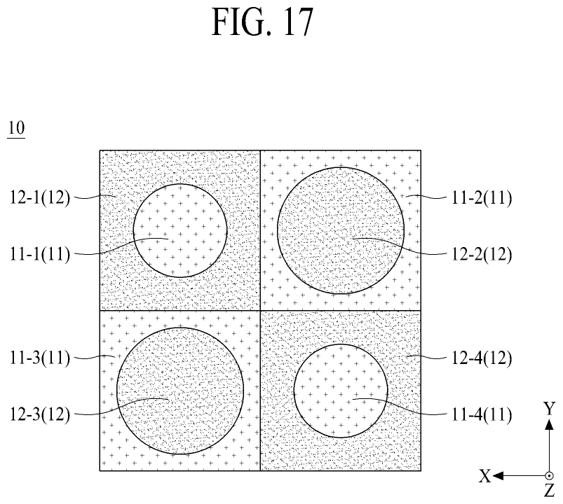

FIGS. 11 to 17 illustrate an arrangement structure of a piezoelectric device according to another embodiment of the present disclosure. FIGS. 11 to 17 illustrate an embodiment where an arrangement structure of a piezoelectric device is one-dimensionally provided in the piezoelectric devices 1, 2, and 3 described above with reference to FIGS. 1 to 10. In the following description, therefore, the same elements other than an arrangement structure of a piezoelectric device and relevant elements are referred to by like reference numerals, and repeated descriptions thereof are omitted or will be briefly given.

Referring to FIG. 11, a piezoelectric device 4 according to another embodiment of the present disclosure can include a first vibration portion 11 and a second vibration portion 12 having different characteristics on the same plane.

Each of the first vibration portion 11 and the second vibration portion 12 can include one or more material portions. For example, the first vibration portion 11 can include a first-1 material portion 11-1 and a first-2 material portion 11-2. Also, the second vibration portion 12 can include a second-1 material portion 12-1 and a second-2 material portion 12-2.

Each of one or more first-1 material portion 11-1 and first-2 material portion 11-2 of the first vibration portion 11 can have a size which differs from that of each of one or more second-1 material portion 12-1 and second-2 material portion 12-2 of the second vibration portion 12.

Each of the first-1 material portion 11-1 and the first-2 material portion 11-2 of the first vibration portion 11 can include a tetragonal shape which has a first length parallel to a first direction X and a second length parallel to a second direction Y intersecting with the first direction X. For example, each of the first-1 material portion 11-1 and the first-2 material portion 11-2 can include a rectangular shape where the second length is longer than the first length.

Each of the second-1 material portion 12-1 and the second-2 material portion 12-2 of the second vibration portion 12 can include a tetragonal shape which has a third length parallel to the first direction X and a fourth length parallel to the second direction Y. For example, each of the second-1 material portion 12-1 and the second-2 material portion 12-2 can include a rectangular shape where the third length is longer than the fourth length.

The first-1 material portion 11-1 and the second-2 material portion 12-2 can be arranged adjacent to each other in the second direction Y. Also, the second-1 material portion 12-1 and the first-2 material portion 11-2 can be arranged adjacent to each other in the second direction Y. For example, the first-1 material portion 11-1 and the second-2 material portion 12-2 adjacent to each other in the second direction Y and the second-1 material portion 12-1 and the first-2 material portion 11-2 adjacent to each other in the second direction Y can be arranged in an asymmetrical structure therebetween.

The first vibration portion 11 and the second vibration portion 12 can include piezoelectric materials having different characteristics. For example, the piezoelectric material can include a BT-based on piezoelectric material and a KNN-based piezoelectric material including K, Na, and Nb. For example, the KNN-based piezoelectric material can include (K,Na)NbO₃, but embodiments of the present disclosure are not limited thereto. For example, the BT-based piezoelectric material can include (Ba,Ca)TiO₃—Ba(Ti,Zr)O₃, but embodiments of the present disclosure are not limited thereto. For example, the KNN-based piezoelectric material can have a density of 4.0 g/cm³ to 4.7 g/cm³, and the BT-based piezoelectric material can have a density of 5.7 g/cm³ to 6.0 g/cm³. Therefore, because the KNN-based piezoelectric material has a density which is lower than that of the BT-based piezoelectric material, a relatively large blocking force can act thereon, and due to this, vibration intensity can be weakened. Accordingly, in the piezoelectric device 4 according to another embodiment of the present disclosure, the first vibration portion 11 having an area which is relatively greater than that of the second vibration portion 12 can include the KNN-based piezoelectric material and the second vibration portion 12 can include the BT-based piezoelectric material, and thus, a reduction in vibration intensity of the KNN-based piezoelectric material can be complemented.

Referring to FIG. 12, a piezoelectric device 5 according to another embodiment of the present disclosure can include a first vibration portion 11 and a second vibration portion 12 having different characteristics on the same plane.

Each of the first vibration portion 11 and the second vibration portion 12 can include a single material portion. For example, the first vibration portion 11 can include a single material portion 11. Also, the second vibration portion 12 can include a single material portion 12. The first vibration portion 11 and the second vibration portion 12 can have different sizes. Also, the first vibration portion 11 and the second vibration portion 12 can include a circular or ring shape.

The first vibration portion 11 and the second vibration portion 12 can have an asymmetrical structure which differs in size and shape. For example, the second vibration portion 12 can be configured to surround the first vibration portion 11. For example, the second vibration portion 12 can include a ring shape which surrounds the first vibration portion 11, and the first vibration portion 11 can include a circular shape which is surrounded by the second vibration portion 12.

The first vibration portion 11 and the second vibration portion 12 can include piezoelectric materials having different characteristics. For example, the piezoelectric material can include a BT-based on piezoelectric material and a KNN-based piezoelectric material including K, Na, and Nb. For example, the KNN-based piezoelectric material can include (K,Na)NbO₃, but embodiments of the present disclosure are not limited thereto. For example, the BT-based piezoelectric material can include (Ba,Ca)TiO₃—Ba(Ti,Zr)O₃, but embodiments of the present disclosure are not limited thereto. For example, the KNN-based piezoelectric material can have a density of 4.0 g/cm³ to 4.7 g/cm³, and the BT-based piezoelectric material can have a density of 5.7 g/cm³ to 6.0 g/cm³. Therefore, because the KNN-based piezoelectric material has a density which is lower than that of the BT-based piezoelectric material, a relatively large blocking force can act thereon, and due to this, vibration intensity can be weakened. Accordingly, in the piezoelectric device 5 according to another embodiment of the present disclosure, the first vibration portion 11 having an area which is relatively greater than that of the second vibration portion 12 can include the KNN-based piezoelectric material and the second vibration portion 12 can include the BT-based piezoelectric material, and thus, a reduction in vibration intensity of the KNN-based piezoelectric material can be complemented. Also, each of the first vibration portion 11 and the second vibration portion 12 of the piezoelectric device 5 according to another embodiment of the present disclosure can have a circular or ring shape of a concentric circle, and thus, can be implemented to have the same vibration mode.

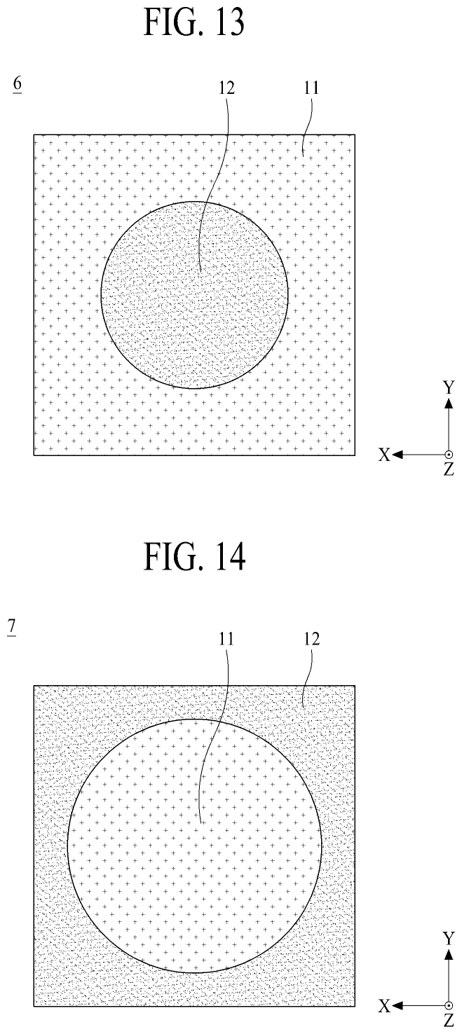

Referring to FIG. 13, a piezoelectric device 6 according to another embodiment of the present disclosure can include a first vibration portion 11 and a second vibration portion 12 having different characteristics on the same plane.

Each of the first vibration portion 11 and the second vibration portion 12 can include a single material portion. For example, the first vibration portion 11 can include a single material portion 11. Also, the second vibration portion 12 can include a single material portion 12. The first vibration portion 11 and the second vibration portion 12 can have different sizes.

The first vibration portion 11 and the second vibration portion 12 can have an asymmetrical structure which differs in size and shape. For example, the second vibration portion 12 can include a circular shape. Also, the first vibration portion 11 can be configured to surround the second vibration portion 12 having a circular shape. For example, the first vibration portion 11 can include a tetragonal or rectangular shape including a circular-shaped hollow portion. The second vibration portion 12 can be disposed or configured in the circular-shaped hollow portion of the first vibration portion 11.

The first vibration portion 11 and the second vibration portion 12 can include piezoelectric materials having different characteristics. For example, the piezoelectric material can include a BT-based on piezoelectric material and a KNN-based piezoelectric material including K, Na, and Nb. For example, the KNN-based piezoelectric material can include (K,Na)NbO₃, but embodiments of the present disclosure are not limited thereto. For example, the BT-based piezoelectric material can include (Ba,Ca)TiO₃—Ba(Ti,Zr)O₃, but embodiments of the present disclosure are not limited thereto. For example, the KNN-based piezoelectric material can have a curie temperature of 170° C. or more, and the BT-based piezoelectric material can have a curie temperature of 100° C. or less, which is relatively lower than that of the KNN-based piezoelectric material. Therefore, the KNN-based piezoelectric material can be better in reliability and heat resistance than the BT-based piezoelectric material. Accordingly, in the piezoelectric device 6 according to another embodiment of the present disclosure, the second vibration portion 12 can include the BT-based piezoelectric material and the first vibration portion 11 surrounding a periphery of the second vibration portion 12 can include the KNN-based piezoelectric material, and thus, the reliability and heat resistance of the piezoelectric device 6 can be improved or enhanced.

Referring to FIG. 14, a piezoelectric device 7 according to another embodiment of the present disclosure can include a first vibration portion 11 and a second vibration portion 12 having different characteristics on the same plane.

Each of the first vibration portion 11 and the second vibration portion 12 can include a single material portion. For example, the first vibration portion 11 can include a single material portion 11. Also, the second vibration portion 12 can include a single material portion 12. The first vibration portion 11 and the second vibration portion 12 can have different sizes. For example, the first vibration portion 11 can have a size which is greater than that of the second vibration portion 12.

The first vibration portion 11 and the second vibration portion 12 can have an asymmetrical structure which differs in size and shape. For example, the first vibration portion 11 can include a circular shape. Also, the second vibration portion 12 can be configured to surround the first vibration portion 11 having a circular shape. For example, the second vibration portion 12 can include a tetragonal or rectangular shape including a circular-shaped hollow portion. The first vibration portion 11 can be disposed or configured in the circular-shaped hollow portion of the second vibration portion 12.

Accordingly, the one of the at least one first vibration portion 11 and the at least one second vibration portion 12 can have a circular shape, and another of the at least one first vibration portion 11 and the at least one second vibration portion 12 can have a non-circular shape that surrounds the circular shape. In embodiments of the present disclosure, the non-circular shape can be a polygon having a circular center, but embodiments of the present disclosure are not limited thereto, and other shapes are possible.

The first vibration portion 11 and the second vibration portion 12 can include piezoelectric materials having different characteristics. For example, the piezoelectric material can include a BT-based on piezoelectric material and a KNN-based piezoelectric material including K, Na, and Nb. For example, the KNN-based piezoelectric material can include (K,Na)NbO₃, but embodiments of the present disclosure are not limited thereto. For example, the BT-based piezoelectric material can include (Ba,Ca)TiO₃—Ba(Ti,Zr)O₃, but embodiments of the present disclosure are not limited thereto. For example, the KNN-based piezoelectric material can have a density of 4.0 g/cm³ to 4.7 g/cm³, and the BT-based piezoelectric material can have a density of 5.7 g/cm³ to 6.0 g/cm³. Therefore, because the KNN-based piezoelectric material has a density which is lower than that of the BT-based piezoelectric material, a relatively large blocking force can act thereon, and due to this, vibration intensity can be weakened. Accordingly, in the piezoelectric device 7 according to another embodiment of the present disclosure, the first vibration portion 11 having an area which is relatively greater than that of the second vibration portion 12 can include the KNN-based piezoelectric material and the second vibration portion 12 can include the BT-based piezoelectric material, and thus, a reduction in vibration intensity of the KNN-based piezoelectric material can be complemented.

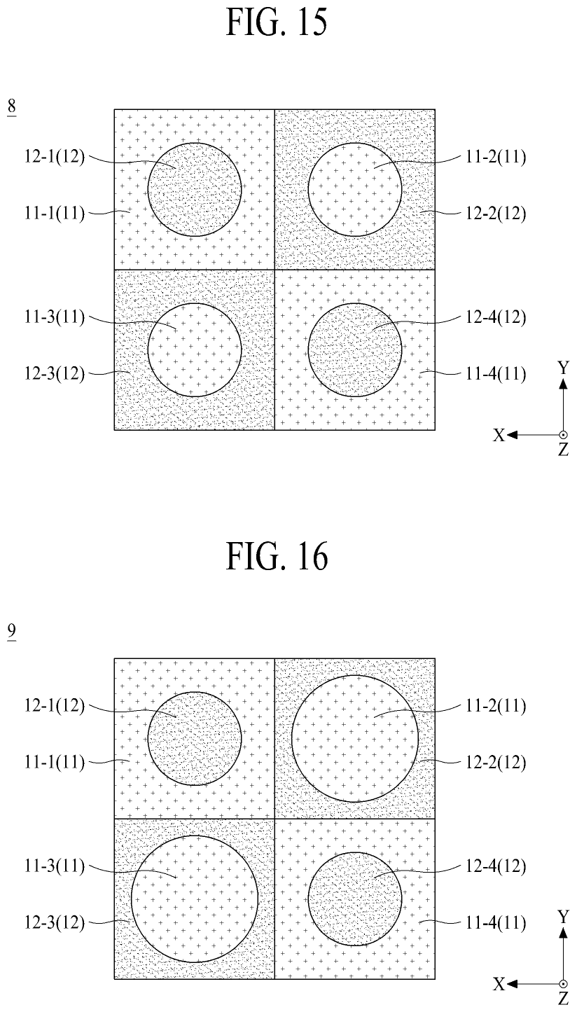

Referring to FIGS. 15 to 17, piezoelectric devices 8, 9, and 10 according to another embodiment of the present disclosure can be disposed or configured as a matrix type where the piezoelectric device 6 illustrated in FIG. 13 and the piezoelectric device 7 illustrated in FIG. 14 are combined as various types.

In the piezoelectric devices 4, 5, 6, 7, 8, 9, and 10 according to another embodiment of the present disclosure, an apparatus satisfying various desired conditions of a piezoelectric driving characteristic can be easily manufactured by various combinations of the first vibration portion 11 and the second vibration portion 12.

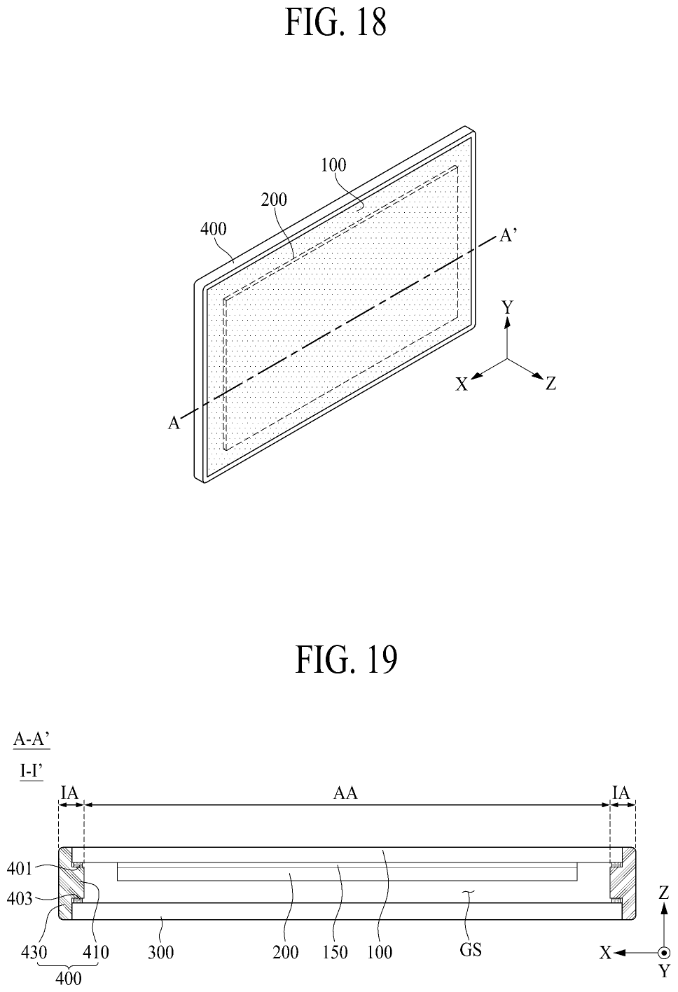

FIG. 18 illustrates an apparatus according to an embodiment of the present disclosure. FIG. 19 is a cross-sectional view taken along line A-A′ of FIG. 18 according to an embodiment of the present disclosure.

Referring to FIGS. 18 and 19, an apparatus according to an embodiment of the present disclosure can be implemented or provided as a sound apparatus, a sound output apparatus, a vibration apparatus, a vibration generating apparatus, a sound bar, a sound system, a sound apparatus for electronic apparatuses, a sound apparatus for display apparatuses, a sound apparatus for vehicular apparatus, or a sound bar for vehicular apparatus. For example, the vehicular apparatus or the transporting apparatus can include one or more of seat and one or more of window. For example, the vehicular apparatus or the transporting apparatus can include a vehicle, a train, a ship, or an aircraft, but embodiments of the present disclosure are not limited thereto. The apparatus according to an embodiment of the present disclosure can be implemented or provided as a signage panel such as an analog signage or digital signage such as an advertisement signboard, a poster, and a guide board.

The apparatus according to an embodiment of the present disclosure can be a display apparatus which includes a plurality of pixels, but embodiments of the present disclosure are not limited thereto.

The display apparatus can include a display panel, including a plurality of pixels implementing a black and white, or color image, and a driver for driving the display panel. Each of the plurality of pixels can be a subpixel configuring one of a plurality of colors implementing a color image. An apparatus according to an embodiment of the present disclosure can include a notebook computer, a television (TV), a computer monitor, an equipment apparatus including a specific form of a vehicle or a vehicular or automotive apparatus, and a set device (or a set apparatus) or a set electronic apparatus such as a smartphone or an electronic pad, which are complete products (or final products) including a display panel such as a liquid crystal display panel or an organic light emitting display panel.

Referring to FIG. 18, the apparatus according to an embodiment of the present disclosure can include a vibration member 100 and a vibration apparatus 200.

The vibration member 100 can generate or output a vibration (or a sound wave), based on a displacement (or driving) of the vibration apparatus 200. The vibration member 100 can be a vibration object, a display member, a display panel, a signage panel, a passive vibration member, a passive vibration plate, a front member, a rear member, a vibration panel, a sound panel, a passive vibration panel, a sound output plate, a sound vibration plate, or an image screen, but embodiments of the present disclosure are not limited thereto.

The vibration member 100 can include one or more of a display panel including a pixel configured to display an image, a screen panel on which an image is to be projected from a display apparatus, a lighting panel, a signage panel, a vehicular interior material, a vehicular glass window, a vehicular exterior material, a ceiling material of a building, an interior material of a building, a glass window of a building, an interior material of an aircraft, and a glass window of an aircraft. For example, the vibration member 100 can include one or more of wood, plastic, glass, metal, cloth, fiber, paper, rubber, leather, carbon, and mirror.

Hereinafter, an example where the vibration member 100 is a display panel will be described.

The display panel 100 can display an image, and for example, can display an image (for example, an electronic image, a digital image, a still image, or a video image). For example, the display panel 100 can emit light to display an image. The display panel 100 can be a curved display panel or all types of display panels such as a liquid crystal display panel, an organic light emitting display panel, a quantum dot light emitting display panel, a micro light emitting diode display panel, and an electrophoresis display panel. The display panel 100 can be a flexible display panel. For example, the display panel 100 can be a flexible light emitting display panel, a flexible electrophoresis display panel, a flexible electro-wetting display panel, a flexible micro light emitting diode display panel, or a flexible quantum dot light emitting display panel, but embodiments of the present disclosure are not limited thereto.

The display panel 100 according to an embodiment of the present disclosure can include a display area AA which displays an image on the basis of driving of a plurality of pixels. Also, the display panel 100 can further include a non-display area IA which surrounds the display area AA, but embodiments of the present disclosure are not limited thereto.

The vibration apparatus 200 can be configured to vibrate the display panel 100. For example, the vibration apparatus 200 can vibrate the display panel 100 at a rear surface of the display panel 100, and thus, can provide a user with a sound and/or a haptic feedback on the basis of a vibration of the display panel 100. The vibration apparatus 200 can be implemented at the rear surface of the display panel 100 to directly vibrate the display panel 100.

According to an embodiment of the present disclosure, the vibration apparatus 200 can vibrate based on a vibration driving signal synchronized with an image displayed by the display panel 100, thereby vibrating the display panel 100. According to another embodiment of the present disclosure, the vibration apparatus 200 can vibrate based on a haptic feedback signal (or a tactile feedback signal) synchronized with a user touch applied to a touch panel (or a touch sensor layer) which is disposed on the display panel 100 or embedded in the display panel 100, and thus, can vibrate the display panel 100. Accordingly, the display panel 100 can vibrate based on a vibration of the vibration apparatus 200 to provide a user (or a viewer) with one or more of a sound and a haptic feedback.

The vibration apparatus 200 according to an embodiment of the present disclosure can be implemented to have a size corresponding to the display area AA of the display panel 100. A size of the vibration apparatus 200 can be 0.9 to 1.1 times a size of the display area AA of the display panel 100, but embodiments of the present disclosure are not limited thereto. For example, a size of the vibration apparatus 200 can be less than or equal to that of the display area AA. For example, a size of the vibration apparatus 200 can be equal to or almost equal to that of the display area AA of the display panel 100, and thus, can cover a large region of the display panel or the display panel 100 and a vibration generated by the vibration apparatus 200 can vibrate a whole region of the display panel 100, thereby enhancing satisfaction of a user and increasing a sense of orientation of a sound. Also, a contact area (or a panel coverage) between the display panel 100 and the vibration apparatus 200 can increase, and thus, a vibration region of the display panel 100 can increase, thereby enhancing a sound of a middle-low pitched sound band generated based on a vibration of the display panel 100. Also, the vibration apparatus 200 applied to a large-sized apparatus can vibrate all of the display panel 100 having a large size (or a large area), and thus, a sense of orientation of a sound based on a vibration of the display panel 100 can be more enhanced, thereby realizing an enhanced sound effect. Accordingly, the vibration apparatus 200 according to an embodiment of the present disclosure can be disposed at the rear surface of the display panel 100 to sufficiently vibrate the display panel 100 in a vertical (or forward and rearward) direction, thereby outputting a desired sound in a forward direction of the apparatus or the display apparatus.

The vibration apparatus 200 according to an embodiment of the present disclosure can be implemented as a film type. Because the vibration apparatus 200 is implemented as a film type, the vibration apparatus 200 can have a thickness which is thinner than the display panel 100, thereby minimizing an increase in thickness of the apparatus caused by the arrangement of the vibration apparatus 200. For example, the vibration apparatus 200 can be referred to as a sound generating module, a vibration generating apparatus, a film actuator, a film type piezoelectric composite actuator, a film speaker, a film type piezoelectric speaker, or a film type piezoelectric composite speaker, which uses the display panel 100 as a sound vibration plate, but embodiments of the present disclosure are not limited thereto.

In another embodiment of the present disclosure, the vibration apparatus 200 may not be disposed at the rear surface of the display panel 100 and can be applied to a vibration object instead of the display panel 100. For example, the vibration object can be a non-display panel, a mirror, an interior material of a vehicle, a glass window of a vehicle, an indoor ceiling of a building, a glass window of a building, an interior material of an aircraft, or a glass window of an aircraft, but embodiments of the present disclosure are not limited thereto. For example, the vibration object can be a sound panel or a sound plate including one or more materials of wood, metal, plastic, glass, cloth, paper, fiber, rubber, leather, and carbon, but embodiments of the present disclosure are not limited thereto. For example, the non-display panel can be a light emitting diode lighting panel (or apparatus), an organic light emitting lighting panel (or apparatus), or an inorganic light emitting lighting panel (or apparatus), but embodiments of the present disclosure are not limited thereto. In this case, a vibration object can be applied as a vibration plate, and the vibration apparatus 200 can vibrate the vibration object to output a sound.

Referring to FIG. 19, the apparatus according to an embodiment of the present disclosure can include a connection member 150 between the vibration apparatus 200 and the display panel 100.

The connection member 150 can include at least one base member and can include an adhesive layer attached on one surface or both surfaces of the base member, or can be configured as a single-layered adhesive layer.

According to an embodiment of the present disclosure, the connection member 150 can include a foam pad, a double-sided tape, a double-sided foam tape, or an adhesive, but embodiments of the present disclosure are not limited thereto. For example, the adhesive layer of the connection member 150 can include epoxy, acryl, silicone, or urethane, but embodiments of the present disclosure are not limited thereto.

The apparatus according to an embodiment of the present disclosure can further include a supporting member 300 which is disposed at the rear surface of the display panel 100.

The supporting member 300 can cover the rear surface of the display panel 100. For example, the supporting member 300 can cover the whole rear surface of the display panel 100 with a gap space GS therebetween. For example, the supporting member 300 can include one or more of a glass material, a metal material, and a plastic material. For example, the supporting member 300 can be a rear structure material or a set structure material. For example, the supporting member 300 can be referred to as the other term such as a cover bottom, a plate bottom, a back cover, a base frame, a metal frame, a metal chassis, a chassis base, or an m-chassis. Therefore, the supporting member 300 can be implemented as an arbitrary type frame or a plate structure material disposed on the rear surface of the display panel 100.

The apparatus according to an embodiment of the present disclosure can further include a middle frame 400.

The middle frame 400 can be disposed between a rear edge of the display panel 100 and a front edge portion of the supporting member 300. The middle frame 400 can support each of one or more of an edge portion of the display panel 100 and an edge portion of the supporting member 300 and can surround one or more of lateral surfaces of each of the display panel 100 and the supporting member 300. The middle frame 400 can provide a gap space GS between the display panel 100 and the supporting member 300. The middle frame 400 can be referred to as a middle cabinet, a middle cover, or a middle chassis, but embodiments of the present disclosure are not limited thereto.

The middle frame 400 according to an embodiment of the present disclosure can include a first supporting portion 410 and a second supporting portion 430.

The first supporting portion 410 can be disposed between the rear edge of the display panel 100 and the front edge of the supporting member 300, and thus, can provide the gap space GS between the display panel 100 and the supporting member 300. A front surface of the first supporting portion 410 can be coupled to or connected with the rear edge portion of the display panel 100 by a first frame connection member 401. A rear surface of the first supporting portion 410 can be coupled to or connected with a front edge portion of the supporting member 300 by a second frame connection member 403. For example, the first supporting portion 410 can have a single picture frame structure having a tetragonal shape, or can include a picture frame structure having a plurality of division bar shapes.

The second supporting portion 430 can be vertically coupled to an outer surface of the first supporting portion 410 in parallel with a thickness direction Z of an apparatus. The second supporting portion 430 can surround one or more of an outer surface of the display panel 100 and an outer surface of the supporting member 300, and thus, can protect the outer surface of each of the display panel 100 and the supporting member 300. The first supporting portion 410 can protrude toward the gap space GS between the display panel 100 and the supporting member 300 from an inner surface of the second supporting portion 430.

The vibration apparatus 200 according to an embodiment of the present disclosure can be the same as or substantially the same as the piezoelectric devices 1 to 10 described above with reference to FIGS. 1 to 17.

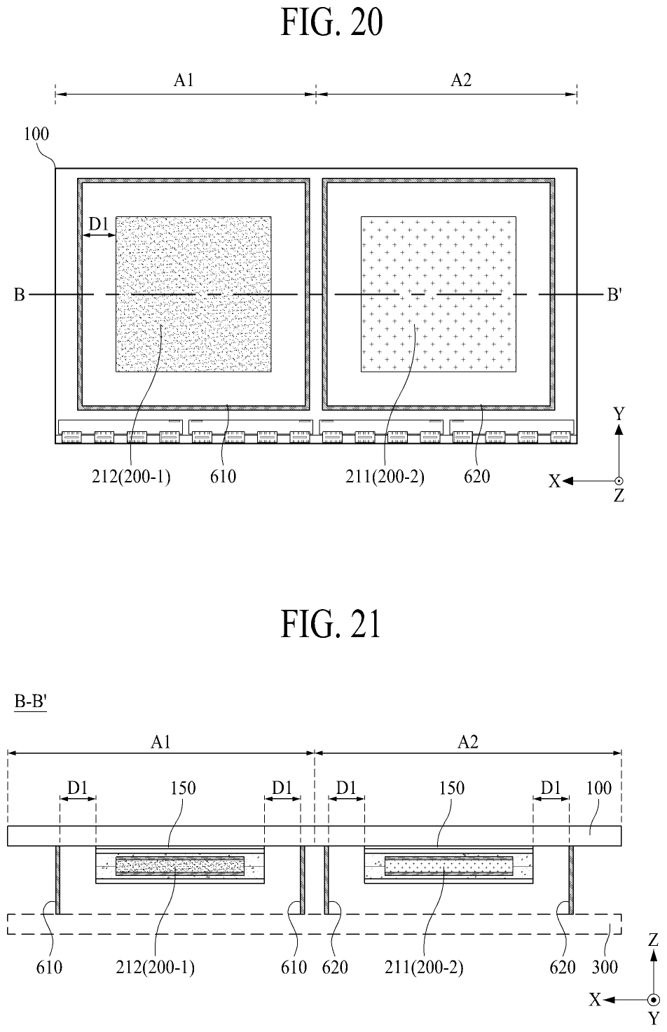

FIG. 20 illustrates a vibration apparatus and a rear surface of a vibration member, in an apparatus according to another embodiment of the present disclosure. FIG. 21 is a cross-sectional view taken along line B-B′ of FIG. 20 according to another embodiment of the present disclosure.

Referring to FIGS. 20 and 21, the apparatus according to an embodiment of the present disclosure can include a plurality of vibration apparatuses 200-1 and 200-2 at a rear surface of a display panel or a vibration member 100. For example, the plurality of vibration apparatuses 200-1 and 200-2 can include a first vibration apparatus 200-1 and a second vibration apparatus 200-2.

The first vibration apparatus 200-1 can be configured in a first region A1 of the display panel or the vibration member 100. For example, the first region A1 of the display panel or the vibration member 100 can be a first rear region, a left region, or a rear left region. According to an embodiment of the present disclosure, the first vibration apparatus 200-1 can be configured to have a size (or area) which is less than that of the first region A1 of the display panel or the vibration member 100. For example, the first vibration apparatus 200-1 can be configured to have a square shape in the first region A1 of the display panel or the vibration member 100. Except for that the first vibration apparatus 200-1 is configured in the first region A1 of the display panel or the vibration member 100, the first vibration apparatus 200-1 can be the same or substantially the same as the piezoelectric devices 1 to 10 described above with reference to FIGS. 1 to 17. According to an embodiment of the present disclosure, the first vibration apparatus 200-1 can include a second vibration portion 212. The second vibration portion 212 can include a single material portion. For example, the second vibration portion 212 can include a Pb-free piezoelectric material.

The second vibration apparatus 200-2 can be configured in a second region A2 of the display panel or the vibration member 100. For example, the second region A2 of the display panel or the vibration member 100 can be a second rear region, a right region, or a rear right region. According to an embodiment of the present disclosure, the second vibration apparatus 200-2 can be configured to have a size (or area) which is less than that of the second region A2 of the display panel or the vibration member 100. For example, the second vibration apparatus 200-2 can be configured to have a square shape in the second region A2 of the display panel or the vibration member 100. Except for that the second vibration apparatus 200-2 is configured in the second region A2 of the display panel or the vibration member 100, the second vibration apparatus 200-2 can be the same or substantially the same as the piezoelectric devices 1 to 10 described above with reference to FIGS. 1 to 17. According to an embodiment of the present disclosure, the second vibration apparatus 200-2 can include a first vibration portion 211. The first vibration portion 211 can include a single material portion. For example, the first vibration portion 211 can include a Pb-free piezoelectric material.

According to another embodiment of the present disclosure, the second vibration portion 212 of the first vibration apparatus 200-1 and the first vibration portion 211 of the second vibration apparatus 200-2 can include Pb-free piezoelectric materials having different characteristics. For example, the first vibration portion 211 and the second vibration portion 212 can include different Pb-free piezoelectric materials having a complementary characteristic. For example, the first vibration portion 211 can include a piezoelectric material having a relative density of 90% or more and a curie temperature of 170° C. or more. For example, the first vibration portion 211 can include a KNN-based piezoelectric material including K, Na, and Nb. For example, the KNN-based piezoelectric material can include (K,Na)NbO₃, but embodiments of the present disclosure are not limited thereto. Also, the second vibration portion 212 can include a piezoelectric material having a relative density of 95% or more and a piezoelectric constant of 700 pC/N or more. For example, the second vibration portion 212 can include a BT-based piezoelectric material. For example, the BT-based piezoelectric material can include (Ba, Ca)TiO₃—Ba(Ti,Zr)O₃, but embodiments of the present disclosure are not limited thereto.

The first vibration apparatus 200-1 and the second vibration apparatus 200-2 can be configured to be horizontally symmetrical with each other with respect to a center between the first region A1 and a second region A2 of the display panel or the vibration member 100, but are not limited thereto and can be configured to be horizontally asymmetrical.

The apparatus according to another embodiment of the present disclosure can further include partitions 610 and 620 which divide the first region A1 and the second region A2 of the display panel or the vibration member 100.

The partitions 610 and 620 can be an air gap or a space where a sound is generated when the display panel or the vibration member 100 is vibrated by the first and second vibration apparatuses 200-1 and 200-2. For example, the partitions 610 and 620 can separate a sound or can separate a channel, and moreover, can prevent or decrease a reduction in characteristic of a sound caused by interference of the sound. The partitions 610 and 620 can be disposed between the display panel or the vibration member 100 and a supporting member 300. For example, the partitions 610 and 620 can be disposed between a rear surface of the display panel or the vibration member 100 and a front surface of the supporting member 300. To decrease an adverse effect of the partitions 610 and 620 on the image quality of the display panel or the vibration member 100, the partitions 610 and 620 can be disposed in the supporting member 300. The partitions 610 and 620 can be referred to as a sound blocking member, a sound separation member, a space separation member, an enclosure, or a baffle, but embodiments of the present disclosure are not limited to the terms.

The partitions 610 and 620 according to an embodiment of the present disclosure can include a first partition member 610 surrounding the first vibration apparatus 200-1 and a second partition member 620 surrounding the second vibration apparatus 200-2.

The first partition member 610 can be disposed between the first region A1 of the display panel or the vibration member 100 and the supporting member 300 to surround the first vibration apparatus 200-1. The first partition member 610 can be disposed between the first region A1 of the display panel or the vibration member 100 and the supporting member 300 so as to be spaced apart from the first vibration apparatus 200-1 by a certain distance. The first partition member 610 can provide a first air gap surrounding the first vibration apparatus 200-1 between the display panel or the vibration member 100 and the supporting member 300. For example, the first partition member 610 can be disposed between the supporting member 300 and the first region A1 of the vibration member 100 corresponding to the first region A1 of the display panel or the vibration member 100. For example, the first partition member 610 can define or limit a vibration region (or a vibration area) of the first region A1 of the display panel or the vibration member 100 by the first vibration apparatus 200-1.

The second partition member 620 can be disposed between the second region A2 of the display panel or the vibration member 100 and the supporting member 300 to surround the second vibration apparatus 200-2. The second partition member 620 can be disposed between the second region A2 of the display panel or the vibration member 100 and the supporting member 300 so as to be spaced apart from the second vibration apparatus 200-2 by a certain distance. The second partition member 620 can provide a second air gap surrounding the second vibration apparatus 200-2 between the display panel or the vibration member 100 and the supporting member 300. For example, the second partition member 620 can be disposed between the supporting member 300 and the second region A2 of the vibration member 100 corresponding to the second region A2 of the display panel or the vibration member 100. For example, the second partition member 620 can define or limit a vibration region (or a vibration area) of the second region A2 of the display panel or the vibration member 100 by the second vibration apparatus 200-2.

The first air gap and a second air gap can each be a sound separation space, a sound blocking space, or a sound interference prevention space, but embodiments of the present disclosure are not limited thereto.

The first and second partition members 610 and 620 can separate the first sound generated by the first vibration apparatus 200-1 and the second sound generated by the second vibration apparatus 200-2. For example, the first and second partition members 610 and 620 can prevent a vibration, generated in the first region A1 of the display panel or the vibration member 100 by the first vibration apparatus 200-1, from being transferred to the second region A2 of the display panel or the vibration member 100, or can prevent a vibration, generated in the second region A2 of the display panel or the vibration member 100 by the second vibration apparatus 200-2, from being transferred to the first region A1 of the display panel or the vibration member 100. Therefore, the first and second partition members 610 and 620 can attenuate or absorb a vibration of the display panel or the vibration member 100 at a center of the display panel or the vibration member 100, and thus, can prevent a sound of the first region A1 from being transferred to the second region A2 or can prevent a sound of the second region A2 from being transferred to the first region A1. Accordingly, the first and second partition members 610 and 620 can separate a left sound and a right sound to further enhance a sound output characteristic of the display apparatus, and thus, the display apparatus according to an embodiment of the present disclosure can output a 2-channel sound and/or a stereo sound, including a 2-channel, in the forward direction of the display panel or the vibration member 100 based on the separation of the left and right sounds by the first and second partition members 610 and 620.

According to an embodiment of the present disclosure, each of the partitions 610 and 620 can include a material having elasticity, which is capable of being compressed to certain degree, but embodiments of the present disclosure are not limited thereto. In an embodiment of the present disclosure, each of the partitions 610 and 620 can include polyurethane or polyolefin, but embodiments of the present disclosure are not limited thereto. In another embodiment of the present disclosure, each of the partitions 610 and 620 can include an adhesive, a single-sided adhesive, a double-sided adhesive, a single-sided tape, a single-sided foam tape, a double-sided tape, or a double-sided foam tape, but embodiments of the present disclosure are not limited thereto.

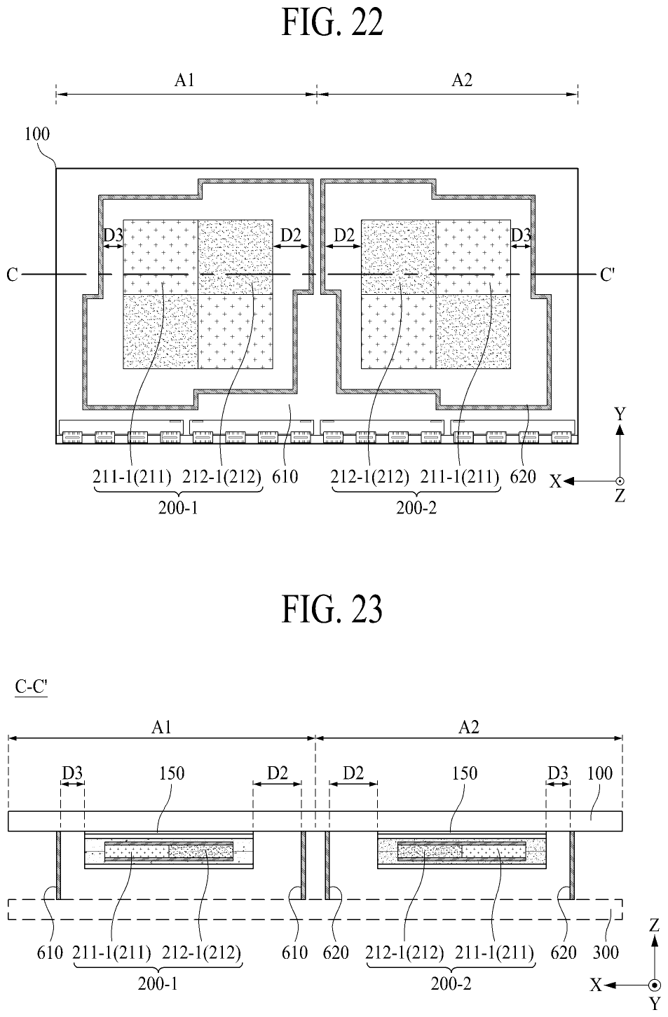

FIG. 22 illustrates a vibration apparatus and a rear surface of a vibration member, in an apparatus according to another embodiment of the present disclosure. FIG. 23 is a cross-sectional view taken along line C-C′ of FIG. 22 according to another embodiment of the present disclosure. FIGS. 22 and 23 illustrate an embodiment implemented by modifying the vibration apparatus and the partition in the apparatus described above with reference to FIGS. 20 and 21. In the following description, therefore, the same elements other than configurations of a vibration apparatus and a partition and relevant elements are referred to by like reference numerals, and repeated descriptions thereof are omitted or will be briefly given.

Referring to FIGS. 22 and 23, the apparatus according to an embodiment of the present disclosure can include a plurality of vibration apparatuses 200-1 and 200-2 at a rear surface of a display panel or a vibration member 100. For example, the plurality of vibration apparatuses 200-1 and 200-2 can include a first vibration apparatus 200-1 and a second vibration apparatus 200-2.

The first vibration apparatus 200-1 can be configured in a first region A1 of the display panel or the vibration member 100. For example, the first region A1 of the display panel or the vibration member 100 can be a first rear region, a left region, or a rear left region. According to an embodiment of the present disclosure, the first vibration apparatus 200-1 can be configured to have a size (or area) which is less than that of the first region A1 of the display panel or the vibration member 100. For example, the first vibration apparatus 200-1 can be configured to have a square shape in the first region A1 of the display panel or the vibration member 100. Except for that the first vibration apparatus 200-1 is configured in the first region A1 of the display panel or the vibration member 100, the first vibration apparatus 200-1 can be the same or substantially the same as the piezoelectric devices 1 to 10 described above with reference to FIGS. 1 to 17. According to another embodiment of the present disclosure, the first vibration apparatus 200-1 can include a first vibration portion 211 and a second vibration portion 212 which are on the same plane and have different characteristics.

The second vibration apparatus 200-2 can be configured in a second region A2 of the display panel or the vibration member 100. For example, the second region A2 of the display panel or the vibration member 100 can be a second rear region, a right region, or a rear right region. According to an embodiment of the present disclosure, the second vibration apparatus 200-2 can be configured to have a size (or area) which is less than that of the second region A2 of the display panel or the vibration member 100. For example, the second vibration apparatus 200-2 can be configured to have a square shape in the second region A2 of the display panel or the vibration member 100. Except for that the second vibration apparatus 200-2 is configured in the second region A2 of the display panel or the vibration member 100, the second vibration apparatus 200-2 can be the same or substantially the same as the piezoelectric devices 1 to 10 described above with reference to FIGS. 1 to 17. According to another embodiment of the present disclosure, the second vibration apparatus 200-2 can include a first vibration portion 211 and a second vibration portion 212 which are on the same plane and have different characteristics.

Except for that the first vibration portion 211 and the second vibration portion 212 of the first vibration apparatus 200-1 and the first vibration portion 211 and the second vibration portion 212 of the second vibration apparatus 200-2 are provided in different regions A1 and A2 of the display panel or the vibration member 100 and arrangement directions thereof are symmetrical with each other, the first vibration portion 211 and the second vibration portion 212 of the first vibration apparatus 200-1 can be the same as or substantially the same as the first vibration portion 211 and the second vibration portion 212 of the second vibration apparatus 200-2.

The first vibration portion 211 and the second vibration portion 212 of the first vibration apparatus 200-1 and the second vibration apparatus 200-2 can each include a piezoelectric material having a piezoelectric effect (or piezoelectric characteristic). For example, each of the first vibration portion 211 and the second vibration portion 212 can be an inorganic layer, an inorganic material layer, a piezoelectric material layer, an electroactive layer, a piezoelectric portion, an inorganic portion, an inorganic piezoelectric portion, a piezoelectric material portion, or an electroactive portion, but embodiments of the present disclosure are not limited thereto. The first vibration portion 211 and the second vibration portion 212 of the first vibration apparatus 200-1 and the second vibration apparatus 200-2 can include Pb-free piezoelectric materials having different characteristics.

The different characteristics of the first vibration portion 211 and the second vibration portion 212 can include one or more of a curie temperature (TC), a piezoelectric constant (d₃₃), a coercive field (EC), a relative density (%), a theoretical density or specific gravity, and a dielectric constant (¿). For example, the first vibration portion 211 and the second vibration portion 212 can include one or more of different characteristics.

Each of the first vibration portion 211 and the second vibration portion 212 according to an embodiment of the present disclosure can include one or more material portions. For example, the first vibration portion 11 can include one or more first material portions 211-1 and 211-2. Also, the second vibration portion 212 can include one or more second material portions 212-1 and 212-2. The one or more first material portions 211-1 and 211-2 and the one or more second material portions 212-1 and 212-2 can have different characteristics. For example, the one or more first material portions 211-1 and 211-2 and the one or more second material portions 212-1 and 212-2 can include piezoelectric materials having different characteristics. For example, the one or more first material portions 211-1 and 211-2 and the one or more second material portions 212-1 and 212-2 can include Pb-free piezoelectric materials. For example, the one or more first material portions 211-1 and 211-2 and the one or more second material portions 212-1 and 212-2 can include Pb-free piezoelectric materials having different characteristics.

According to an embodiment of the present disclosure, each of the one or more first material portions 211-1 and 211-2 can include a piezoelectric material including one or more of a higher curie temperature and a less piezoelectric constant than those of each of the one or more second material portions 212-1 and 212-2.

Each of the one or more first material portions 211-1 and 211-2 can include one or more of a relative density of 90% or more and a curie temperature of 170° C. or more. For example, each of the one or more first material portions 211-1 and 211-2 can include a piezoelectric material having a relative density of 90% or more and a curie temperature of 170° C. or more. For example, each of the one or more first material portions 211-1 and 211-2 can include a KNN-based piezoelectric material including K, Na, and Nb. For example, the KNN-based piezoelectric material can include (K,Na)NbO₃, but embodiments of the present disclosure are not limited thereto. The one or more first material portions 211-1 and 211-2 can be configured or implemented to enhance the reliability of the vibration apparatus 200.

Each of the one or more second material portions 212-1 and 212-2 can include one or more of a relative density of 95% or more and a piezoelectric constant of 700 pC/N or more. For example, each of the one or more second material portions 212-1 and 212-2 can include a piezoelectric material having a relative density of 95% or more and a piezoelectric constant of 700 pC/N or more. For example, each of the one or more second material portions 212-1 and 212-2 can include a BT-based piezoelectric material. For example, the BT-based piezoelectric material can include (Ba,Ca)TiO₃—Ba(Ti,Zr)O₃, but embodiments of the present disclosure are not limited thereto. The one or more second material portions 212-1 and 212-2 can be configured or implemented to enhance a driving characteristic of the vibration apparatus 200.

The one or more first material portions 211-1 and 211-2 and the one or more second material portions 212-1 and 212-2 according to an embodiment of the present disclosure can have different thicknesses or the same thickness. For example, the one or more first material portions 211-1 and 211-2 and the one or more second material portions 212-1 and 212-2 can have substantially the same height within an error range of a manufacturing process. Also, the one or more first material portions 211-1 and 211-2 and the one or more second material portions 212-1 and 212-2 can have different sizes or the same size. For example, the one or more first material portions 211-1 and 211-2 and the one or more second material portions 212-1 and 212-2 can have substantially the same size within an error range of a manufacturing process. Also, the number of one or more first material portions 211-1 and 211-2 can be equal to or different from the number of one or more second material portions 212-1 and 212-2. For example, the number of one or more first material portions 211-1 and 211-2 can be equal to the number of one or more second material portions 212-1 and 212-2. For example, the one or more first material portions 211-1 and 211-2 can include a first-1 material portion 211-1 and a first-2 material portion 211-2. For example, the one or more second material portions 212-1 and 212-2 can include a second-1 material portion 212-1 and a second-2 material portion 212-2.

Each of the one or more first material portions 211-1 and 211-2 and the one or more second material portions 212-1 and 212-2 can include a tetragonal shape which has a first length parallel to a first direction X and a second length parallel to a second direction Y intersecting with the first direction X. For example, each of the one or more first material portions 211-1 and 211-2 and the one or more second material portions 212-1 and 212-2 can include a square shape where the first length is equal to the second length, but embodiments of the present disclosure are not limited thereto.

The one or more first material portions 211-1 and 211-2 and the one or more second material portions 212-1 and 212-2 can be arranged apart from each other in a first direction X or a second direction Y on the same plane. For example, the first-1 material portion 211-1 and the second-1 material portion 212-1 can be arranged adjacent to each other in the first direction X. The first-1 material portion 211-1 and the second-1 material portion 212-1 can be arranged in parallel in the second direction Y. Also, the first-1 material portion 211-1 can be disposed at a left periphery of the second-1 material portion 212-1, and the second-1 material portion 212-1 can be disposed at a right periphery of the first-1 material portion 211-1. Also, the second-2 material portion 212-2 and the first-2 material portion 211-2 can be arranged adjacent to each other in the first direction X. The second-2 material portion 212-2 and the first-2 material portion 211-2 can be arranged in parallel in the second direction Y. Also, the second-2 material portion 212-2 can be disposed at a left periphery of the first-2 material portion 211-2, and the first-2 material portion 211-2 can be disposed at a right periphery of the second-2 material portion 212-2. Also, the first-1 material portion 211-1 and the second-2 material portion 212-2 can be arranged adjacent to each other in the second direction Y. The first-1 material portion 211-1 and the second-2 material portion 212-2 can be arranged in parallel in the first direction X. Also, the first-1 material portion 211-1 can be disposed at an upper periphery of the second-2 material portion 212-2, and the second-2 material portion 212-2 can be disposed at a lower periphery of the first-1 material portion 211-1. Also, the second-1 material portion 212-1 and the first-2 material portion 211-2 can be arranged adjacent to each other in the second direction Y. The second-1 material portion 212-1 and the first-2 material portion 211-2 can be arranged in parallel in the first direction X. Also, the second-1 material portion 212-1 can be disposed at an upper periphery of the first-2 material portion 211-2, and the first-2 material portion 211-2 can be disposed at a lower periphery of the second-1 material portion 212-1. For example, an example is described where the one or more first material portions 211-1 and 211-2 and the one or more second material portions 212-1 and 212-2 are included in the first vibration apparatus 200-1, but except for that an arrangement direction of the one or more first material portions 211-1 and 211-2 and the one or more second material portions 212-1 and 212-2 included in the first vibration apparatus 200-1 is symmetrical with an arrangement direction of the one or more first material portions 211-1 and 211-2 and the one or more second material portions 212-1 and 212-2 included in the second vibration apparatus 200-2, the one or more first material portions 211-1 and 211-2 and the one or more second material portions 212-1 and 212-2 included in the first vibration apparatus 200-1 can be the same as or substantially the same as the one or more first material portions 211-1 and 211-2 and the one or more second material portions 212-1 and 212-2 included in the second vibration apparatus 200-2.

The first vibration apparatus 200-1 and the second vibration apparatus 200-2 can be configured to be horizontally symmetrical with each other with respect to a center between the first region A1 and a second region A2 of the display panel or the vibration member 100, but are not limited thereto and can be configured to be horizontally asymmetrical.

The apparatus according to another embodiment of the present disclosure can further include partitions 610 and 620 which divide the first region A1 and the second region A2 of the display panel or the vibration member 100.

The partitions 610 and 620 can be an air gap or a space where a sound is generated when the display panel or the vibration member 100 is vibrated by the first and second vibration apparatuses 200-1 and 200-2. For example, the partitions 610 and 620 can separate a sound or can separate a channel, and moreover, can prevent or decrease a reduction in characteristic of a sound caused by interference of the sound. The partitions 610 and 620 can be disposed between the display panel or the vibration member 100 and a supporting member 300. For example, the partitions 610 and 620 can be disposed between a rear surface of the display panel or the vibration member 100 and a front surface of the supporting member 300. To decrease an adverse effect of the partitions 610 and 620 on the image quality of the display panel or the vibration member 100, the partitions 610 and 620 can be disposed in the supporting member 300. The partitions 610 and 620 can be referred to as a sound blocking member, a sound separation member, a space separation member, an enclosure, or a baffle, but embodiments of the present disclosure are not limited to the terms.

The partitions 610 and 620 according to an embodiment of the present disclosure can include a first partition member 610 surrounding the first vibration apparatus 200-1 and a second partition member 620 surrounding the second vibration apparatus 200-2.

A first partition member 610 can be disposed between the first region A1 of the display panel or the vibration member 100 and a supporting member 300 to surround the first vibration apparatus 200-1. According to another embodiment of the present disclosure, the first partition member 610 can be disposed or configured apart from a periphery of the first vibration apparatus 200-1 to have different distances. For example, the first partition member 610 can be disposed between the first region A1 of the display panel or the vibration member 100 and the supporting member 300 so as to be spaced apart from some peripheries of the first vibration apparatus 200-1 by a second distance D2. Also, the first partition member 610 can be disposed between the first region A1 of the display panel or the vibration member 100 and the supporting member 300 so as to be spaced apart from the other periphery of the first vibration apparatus 200-1 by a third distance D3. For example, the one or more first material portions 211-1 and 211-2 of the first vibration apparatus 200-1 can include a KNN-based piezoelectric material, and the one or more second material portions 212-1 and 212-2 of the first vibration apparatus 200-1 can include a BT-based piezoelectric material. In this case, the KNN-based piezoelectric material can have a density of 4.0 g/cm³ to 4.7 g/cm³, and the BT-based piezoelectric material can have a density of 5.7 g/cm³ to 6.0 g/cm³. Therefore, because the KNN-based piezoelectric material has a density which is lower than that of the BT-based piezoelectric material, vibration intensity can be relatively weakened. Therefore, a large area of an air gap may not be needed at peripheries of the one or more first material portions 211-1 and 211-2 including the KNN-based piezoelectric material, and a sufficient air gap can be easily secured at peripheries of the one or more second material portions 212-1 and 212-2 including the BT-based piezoelectric material. Accordingly, according to another embodiment of the present disclosure, the first partition member 610 can be spaced apart from the one or more first material portions 211-1 and 211-2 by the third distance D3 which is less than the second distance D2, in the first vibration apparatus 200-1, and thus, an area of an air gap can be reduced, and moreover, the first partition member 610 can be spaced apart from the one or more second material portions 212-1 and 212-2 by the second distance D2 in the first vibration apparatus 200-1, and thus, an area of an air gap can be enlarged.

A second partition member 620 can be disposed between the second region A2 of the display panel or the vibration member 100 and a supporting member 300 to surround the second vibration apparatus 200-2. According to another embodiment of the present disclosure, the second partition member 620 can be disposed or configured apart from a periphery of the second vibration apparatus 200-2 to have different distances. For example, the second partition member 620 can be disposed between the second region A2 of the display panel or the vibration member 100 and the supporting member 300 so as to be spaced apart from some peripheries of the second vibration apparatus 200-2 by a second distance D2. Also, the second partition member 620 can be disposed between the second region A2 of the display panel or the vibration member 100 and the supporting member 300 so as to be spaced apart from the other periphery of the second vibration apparatus 200-2 by a third distance D3. For example, the one or more first material portions 211-1 and 211-2 of the second vibration apparatus 200-2 can include a KNN-based piezoelectric material, and the one or more second material portions 212-1 and 212-2 of the second vibration apparatus 200-2 can include a BT-based piezoelectric material. In this case, the KNN-based piezoelectric material can have a density of 4.0 g/cm³ to 4.7 g/cm³, and the BT-based piezoelectric material can have a density of 5.7 g/cm³ to 6.0 g/cm³. Therefore, because the KNN-based piezoelectric material has a density which is lower than that of the BT-based piezoelectric material, vibration intensity can be relatively weakened. Therefore, a large area of an air gap may not be needed at peripheries of the one or more first material portions 211-1 and 211-2 including the KNN-based piezoelectric material, and a sufficient air gap can be easily secured at peripheries of the one or more second material portions 212-1 and 212-2 including the BT-based piezoelectric material. Accordingly, according to another embodiment of the present disclosure, the second partition member 620 can be spaced apart from the one or more first material portions 211-1 and 211-2 by the third distance D3 which is less than the second distance D2, in the second vibration apparatus 200-2, and thus, an area of an air gap can be reduced, and moreover, the second partition member 620 can be spaced apart from the one or more second material portions 212-1 and 212-2 by the second distance D2 in the second vibration apparatus 200-2, and thus, an area of an air gap can be enlarged.

In the apparatus according to another embodiment of the present disclosure, the first vibration portion 211 and the second vibration portion 212 corresponding to a piezoelectric device layer of the vibration apparatus 200 can be without Pb, and the reliability and driving characteristic of vibration apparatus 200 can be enhanced or improved. Also, because the vibration apparatus 200 does not include Pb, a production restriction material can be reduced and replacement of a harmful material can be implemented, and thus, an environment-friendly vibration apparatus 200 and an apparatus including the same can be implemented or realized.

A piezoelectric device and an apparatus including the same according to various embodiments of the present disclosure will be described below.

A piezoelectric device according to various embodiments of the present disclosure can include a piezoelectric device layer, a first electrode layer at a first surface of the piezoelectric device layer, and a second electrode layer at a second surface of the piezoelectric device layer different from the first surface. The piezoelectric device layer can include a first vibration portion and a second vibration portion each provided on a same plane to have different characteristics.

According to various embodiments of the present disclosure, the different characteristics can include one or more of a curie temperature (TC), a piezoelectric constant (d₃₃), a coercive field (EC), a relative density (%), a theoretical density or specific gravity, and a dielectric constant (¿).

According to various embodiments of the present disclosure, one of the first vibration portion and the second vibration portion can include at least one of a relative density of 90% or more and a curie temperature of 170° C. or more.

According to various embodiments of the present disclosure, one of the first vibration portion and the second vibration portion can include one or more of a relative density of 95% or more and a piezoelectric constant of 700 pC/N or more.

According to various embodiments of the present disclosure, the first vibration portion and the second vibration portion can include different materials of a potassium sodium niobite (KNN)-based material, a barium titanate (BT)-based material, and a bismuth (Bi)-based material.

According to various embodiments of the present disclosure, the first vibration portion can include at least one first material portion. The second vibration portion can include at least one second material portion having a characteristic which differs from a characteristic of the at least one first material portion.

According to various embodiments of the present disclosure, the at least one first material portion can have a thickness which is different from or equal to a thickness of the at least one second material portion.

According to various embodiments of the present disclosure, the at least one first material portion and the at least one second material portion can have different sizes or the same size.

According to various embodiments of the present disclosure, the number of at least one first material portion can be different from or equal to the number of at least one second material portion.

According to various embodiments of the present disclosure, the at least one first material portion and the at least one second material portion can be adjacent to each other in a first direction or a second direction intersecting with the first direction on the same plane.

According to various embodiments of the present disclosure, the at least one first material portion and the at least one second material portion can have different shapes or the same shape.

According to various embodiments of the present disclosure, the at least one first material portion can surround a periphery of the at least one second material portion in the same plane.

According to various embodiments of the present disclosure, the first vibration portion can include a plurality of first material portions. The second vibration portion can include a plurality of second material portions having a characteristic which differs from a characteristic of the plurality of first material portions. Each of the plurality of first material portions can be adjacent to at least one of the plurality of second material portions in a first direction or a second direction intersecting with the first direction on the same plane. Each of the plurality of second material portions can be adjacent to at least one of the plurality of first material portions in the first direction and the second direction on the same plane.

According to various embodiments of the present disclosure, one of the plurality of first material portions and one of the plurality of second material portions can have different sizes.

According to various embodiments of the present disclosure, the plurality of first material portions and the plurality of second material portions can be disposed in an asymmetrical structure with each other.

According to various embodiments of the present disclosure, each of the plurality of first material portions can include one or more of a higher curie temperature and a less piezoelectric constant than each of the plurality of second material portions.

According to various embodiments of the present disclosure, each of the plurality of first material portions can include a potassium sodium niobite (KNN)-based material, and each of the plurality of second material portions can include a barium titanate (BT)-based material or a bismuth (Bi)-based material.

According to various embodiments of the present disclosure, each of the at least one first material portion can further include an additive added to the KNN-based material, and the additive can include one or more of CuO, Fe₂O₃, La₂O₃, ZrO₂, ZnO, SnO₂, CdO, MnO₂, CuNb₂O₆, Gd₂O₃, Al₂O₃, CaO, BaO, HfO, TiO₂, Co₂O₃, NiO, MgO, B₂O₃, and SiO₂.

According to various embodiments of the present disclosure, each of the at least one second material portion can further include one or more of a first additive and a second additive each added to the BT-based material or the Bi-based material. The first additive can include one or more of CuO, Fe₂O₃, La₂O₃, ZrO₂, ZnO, SnO₂, CdO, MnO₂, CuNb₂O₆, Gd₂O₃, Al₂O₃, CaO, BaO, HfO, TiO₂, Co₂O₃, NiO, MgO, B₂O₃, and SiO₂. The second additive can include one or more of CaCl₂, AlF₃, BaCl₂, LiF, MgF₂, CaF₂, NaF, KF, NaCl, MgCl₂, KCl, ZnCl₂, LiCl₂, AlCl₃, CaSO₄, CaSO₃, Na₂SO₄, Na₂SO₃, and Na₂S.

According to various embodiments of the present disclosure, each of the first vibration portion and the second vibration portion can be configured so that a plurality of material layers having the same characteristic or different characteristics overlap each other in a thickness direction of the piezoelectric device layer.

According to various embodiments of the present disclosure, the first vibration portion and the second vibration portion can be spaced apart from each other on the same plane.

According to various embodiments of the present disclosure, can further include a coupling member between the first vibration portion and the second vibration portion.

According to various embodiments of the present disclosure, one of the plurality of first material portions and one of the plurality of second material portions can have different sizes.

According to various embodiments of the present disclosure, the plurality of first material portions and the plurality of second material portions can be disposed in an asymmetrical structure with each other.

An apparatus according to various embodiments of the present disclosure can include a vibration member, and at least one vibration apparatus configured to vibrate the vibration member, the at least one vibration apparatus can include a piezoelectric device layer, a first electrode layer at a first surface of the piezoelectric device layer, and a second electrode layer at a second surface of the piezoelectric device layer different from the first surface. The piezoelectric device layer can include a first vibration portion and a second vibration portion each provided on a same plane to have different characteristics.

According to various embodiments of the present disclosure, the vibration member can include one or more of a display panel including a plurality of pixels configured to display an image, a screen panel on which an image is to be projected from a display apparatus, a light emitting diode illumination panel, an organic light emitting illumination panel, an inorganic light emitting illumination panel, a signage panel, a vehicular interior material, a vehicular exterior material, a vehicular glass window, an interior material of a vehicular seat, a ceiling material of a building, an interior material of a building, a window of a building, an interior material of an aircraft, a glass window of an aircraft, and a mirror, or the vibration member can include one or more of metal, plastic, fiber, leather, wood, cloth, rubber, carbon, glass, mirror, and paper.

According to various embodiments of the present disclosure, the vibration member can include a first region and a second region, and the at least one vibration apparatus can include a first vibration apparatus in the first region, and a second vibration apparatus in the second region.

According to various embodiments of the present disclosure, the apparatus can further include a partition between the first region and the second region of the vibration member.

According to various embodiments of the present disclosure, the apparatus can further include a supporting member at one surface of the vibration member. The partition can include one or more of the first and second partition members. The first partition member can be provided between the vibration member and the supporting member to surround the first vibration apparatus. The second partition member can be provided between the vibration member and the supporting member to surround the second vibration apparatus.

According to various embodiments of the present disclosure, the first partition member can be configured to have one or more different separation distances from a periphery of the first vibration apparatus. The second partition member can be configured to have one or more different separation distances from a periphery of the second vibration apparatus.

According to various embodiments of the present disclosure, a piezoelectric device can include a first electrode, a piezoelectric device layer on the first electrode, and having at least one first vibration portion and at least one second vibration portion arranged adjacent to each other along at least a first direction, each of the at least one first vibration portion and the at least one second vibration portion including at least one lead (Pb)-free piezoelectric material having a relative density of 90% or more, and a piezoelectric constant of 650 pC/N or more, and a second electrode on the piezoelectric device layer.

According to various embodiments of the present disclosure, the at least one lead-free piezoelectric material can include a first lead-free piezoelectric material having the relative density of about 90% or more and a curie temperature of about 170° C. or more, or a second lead-free piezoelectric material having the relative density of about 95% or more and the piezoelectric constant of about 700 pC/N or more.

According to various embodiments of the present disclosure, the at least one first vibration portion and the at least one second vibration portion can be rectangular. The at least one first vibration portion can include two first vibration portions and the at least one second vibration portion may include two second vibration portions. The piezoelectric device has four quadrants, and the two first vibration portions can be disposed in a first pair of opposite quadrants, and the two second vibration portions can be disposed in a second pair of opposite quadrants.

According to various embodiments of the present disclosure, each quadrant can have four sub-quadrants.

According to various embodiments of the present disclosure, wherein the at least one first vibration portion can include a plurality of first vibration portions and the at least one second vibration portion can include a plurality of second vibration portions that are further arranged along at least a second direction that intersects the first direction and a third direction that intersects both the first direction and the second direction.

According to various embodiments of the present disclosure, one of the at least one first vibration portion and the at least one second vibration portion can have a circular shape, and another of the at least one first vibration portion and the at least one second vibration portion can have a non-circular shape that surrounds the circular shape.

An apparatus according to an embodiment of the present disclosure can be applied to or included in a sound apparatus provided in the apparatus. The apparatus according to an embodiment of the present disclosure can be applied to or included in mobile apparatuses, video phones, smart watches, watch phones, wearable apparatuses, foldable apparatuses, rollable apparatuses, bendable apparatuses, flexible apparatuses, curved apparatuses, sliding apparatus, variable apparatus, electronic organizers, electronic book, portable multimedia players (PMPs), personal digital assistants (PDAs), MP3 players, mobile medical apparatuses, desktop personal computers (PCs), laptop PCs, netbook computers, workstations, navigation apparatuses, automotive navigation apparatuses, automotive display apparatuses, automotive apparatuses, theatrical apparatuses, theatrical display apparatuses, televisions (TVs), wall paper display apparatuses, signage apparatuses, game machines, notebook computers, monitors, cameras, camcorders, home appliances, etc. Also, the sound apparatus according to embodiments of the present disclosure can be applied to or included in organic light emitting lighting apparatuses or inorganic light emitting lighting apparatuses. In a case where the sound apparatus is applied to or included in a lighting apparatus, the sound apparatus can act as lighting and a speaker. Also, in a case where the sound apparatus according to embodiment of the present disclosure is applied to or included in a mobile apparatus, the sound apparatus can be one or more of a speaker, a receiver, or a haptic, but embodiments of the present disclosure are not limited thereto.

It will be apparent to those skilled in the art that various modifications and variations can be made in the present disclosure without departing from the scope of the present disclosure. Thus, it is intended that the present disclosure covers the modifications and variations of this disclosure provided that within the scope of the claims and their equivalents.

What is claimed is:

1. A piezoelectric device, comprising:
a piezoelectric device layer;
a first electrode layer at a first surface of the piezoelectric device layer; and
a second electrode layer at a second surface of the piezoelectric device layer different from the first surface,
wherein the piezoelectric device layer comprises a first vibration portion and a second vibration portion each provided on a same plane to have different characteristics.

2. The piezoelectric device of claim 1, wherein the different characteristics comprise one or more of a curie temperature (TC), a piezoelectric constant (d₃₃), a coercive field (EC), a relative density (%), a theoretical density or specific gravity, and a dielectric constant (ε).

3. The piezoelectric device of claim 1, wherein one of the first vibration portion and the second vibration portion comprises at least one of a relative density of 90% or more and a curie temperature of about 170° C. or more, or
wherein one of the first vibration portion and the second vibration portion comprises at least one of a relative density of about 95% or more and a piezoelectric constant of about 700 pC/N or more.

4. The piezoelectric device of claim 1, wherein the first vibration portion and the second vibration portion comprise different materials of a potassium sodium niobite (KNN)-based material, a barium titanate (BT)-based material, and a bismuth (Bi)-based material.

5. The piezoelectric device of claim 1, wherein the first vibration portion comprises at least one first material portion, and
wherein the second vibration portion comprises at least one second material portion having a characteristic which differs from a characteristic of the at least one first material portion.

6. The piezoelectric device of claim 5, wherein the at least one first material portion has a thickness which is different from or equal to a thickness of the at least one second material portion, or
wherein the at least one first material portion and the at least one second material portion have different sizes or the same size, or
wherein the number of at least one first material portion is different from or equal to the number of at least one second material portion, or
wherein the at least one first material portion and the at least one second material portion have different shapes or the same shape.

7. The piezoelectric device of claim 5, wherein the at least one first material portion and the at least one second material portion are adjacent to each other in a first direction or a second direction intersecting with the first direction on the same plane.

8. The piezoelectric device of claim 1, wherein the at least one first material portion surrounds a periphery of the at least one second material portion in the same plane.

9. The piezoelectric device of claim 1, wherein the first vibration portion comprises a plurality of first material portions,
wherein the second vibration portion comprises a plurality of second material portions having a characteristic which differs from a characteristic of the plurality of first material portions,
wherein each of the plurality of first material portions is adjacent to at least one of the plurality of second material portions in a first direction or a second direction intersecting with the first direction on the same plane, and
wherein each of the plurality of second material portions is adjacent to at least one of the plurality of first material portions in the first direction and the second direction on the same plane.

10. The piezoelectric device of claim 9, wherein one of the plurality of first material portions and one of the plurality of second material portions have different sizes.

11. The piezoelectric device of claim 10, wherein the plurality of first material portions and the plurality of second material portions are disposed in an asymmetrical structure with each other.

12. The piezoelectric device of claim 9, wherein each of the plurality of first material portions comprises one or more of a higher curie temperature and a less piezoelectric constant than each of the plurality of second material portions.

13. The piezoelectric device of claim 12, wherein each of the plurality of first material portions comprises a potassium sodium niobite (KNN)-based material, and
wherein each of the plurality of second material portions comprises a barium titanate (BT)-based material or a bismuth (Bi)-based material.

14. The piezoelectric device of claim 13, wherein each of the plurality of first material portions further comprises an additive added to the KNN-based material, and
wherein the additive comprises one or more of CuO, FezO₃, La₂O₃, ZrO₂, ZnO, SnO₂, CdO, MnO₂, CuNb₂₀₆, Gd₂O₃, Al₂O₃, CaO, BaO, HfO, TiO₂, Co₂O₃, NiO, MgO, B₂O₃, and SiO₂, or
wherein each of the plurality of second material portions further comprises one or more of a first additive and a second additive each added to the BT-based material or the Bi-based material,
wherein the first additive comprises one or more of CuO, FezO₃, La₂O₃, ZrO₂, ZnO, SnO₂, CdO, MnO₂, CuNb₂O₆, Gd₂O₃, Al₂O₃, CaO, BaO, HO, TiOz, Co₂O₃, NiO, MgO, B₂O₃, and SiO₂, and
wherein the second additive comprises one or more of CaCl₂), AlF₃, BaCl₂, LiF, MgF₂, CaF₂, NaF, KF, NaCl, MgCl₂, KCl, ZnCl₂, LiCl₂, AlCl₃, CaSO₄, CaSO₃, Na₂SO₄, Na₂SO₃, and Na₂S.

15. The piezoelectric device of claim 1, wherein each of the first vibration portion and the second vibration portion is configured so that a plurality of material layers having the same characteristic or different characteristics overlap each other in a thickness direction of the piezoelectric device layer.

16. The piezoelectric device of claim 1, wherein the first vibration portion and the second vibration portion are spaced apart from each other on the same plane, and
a coupling member is disposed between the first vibration portion and the second vibration portion.

17. An apparatus, comprising:
a vibration member; and
at least one vibration apparatus configured to vibrate the vibration member, and comprising the piezoelectric device of claim 1.

18. The apparatus of 17, wherein the vibration member comprises one or more of a display panel including a plurality of pixels configured to display an image, a screen panel on which an image is to be projected from a display apparatus, a light emitting diode illumination panel, an organic light emitting illumination panel, an inorganic light emitting illumination panel, a signage panel, a vehicular interior material, a vehicular exterior material, a vehicular glass window, an interior material of a vehicular seat, a ceiling material of a building, an interior material of a building, a window of a building, an interior material of an aircraft, a glass window of an aircraft, and a mirror, or
wherein the vibration member comprises one or more of metal, plastic, fiber, leather, wood, cloth, rubber, carbon, glass, mirror, and paper.

19. The apparatus of claim 18, wherein the vibration member comprises a first region and a second region, and
wherein the at least one vibration apparatus comprises:
a first vibration apparatus in the first region; and
a second vibration apparatus in the second region.

20. The apparatus of claim 19, further comprising a partition between the first region and the second region of the vibration member.

21. The apparatus of claim 20, further comprising a supporting member at one surface of the vibration member,
wherein the partition comprises one or more of the first and second partition members,
wherein the first partition member is provided between the vibration member and the supporting member to surround the first vibration apparatus, and
wherein the second partition member is provided between the vibration member and the supporting member to surround the second vibration apparatus.

22. The apparatus of claim 21, wherein the first partition member is configured to have one or more different separation distances from a periphery of the first vibration apparatus, and
wherein the second partition member is configured to have one or more different separation distances from a periphery of the second vibration apparatus.

23. A piezoelectric device, comprising:
a first electrode;
a piezoelectric device layer on the first electrode, and having at least one first vibration portion and at least one second vibration portion arranged adjacent to each other along at least a first direction, each of the at least one first vibration portion and the at least one second vibration portion including at least one lead-free piezoelectric material having a relative density of about 90% or more, and a piezoelectric constant of about 650 pC/N or more; and
a second electrode on the piezoelectric device layer.

24. The piezoelectric device of claim 23, wherein the at least one lead-free piezoelectric material includes a first lead-free piezoelectric material having the relative density of about 90% or more and a curie temperature of about 170° C. or more, or a second lead-free piezoelectric material having the relative density of about 95% or more and the piezoelectric constant of about 700 pC/N or more.

25. The piezoelectric device of claim 23, wherein the at least one first vibration portion and the at least one second vibration portion are rectangular,
wherein the at least one first vibration portion includes two first vibration portions and the at least one second vibration portion includes two second vibration portions, and
wherein the piezoelectric device has four quadrants, and the two first vibration portions are disposed in a first pair of opposite quadrants, and the two second vibration portions are disposed in a second pair of opposite quadrants.

26. The piezoelectric device of claim 25, wherein each quadrant has four sub-quadrants.

27. The piezoelectric device of claim 23, wherein the at least one first vibration portion includes a plurality of first vibration portions and the at least one second vibration portion includes a plurality of second vibration portions that are further arranged along at least a second direction that intersects the first direction and a third direction that intersects both the first direction and the second direction.

28. The piezoelectric device of claim 23, wherein one of the at least one first vibration portion and the at least one second vibration portion has a circular shape, and another of the at least one first vibration portion and the at least one second vibration portion has a non-circular shape that surrounds the circular shape.
